(19) United States
(12) Patent Application Publication
(10) Pub. No.: US 2011/0146787 A1
(43) Pub. Date: Jun. 23, 2011

(54) SILICON CARBIDE-BASED ANTIREFLECTIVE COATING

(76) Inventors: Sebastien Allen, St-Lazare (CA); Yousef Awad, Saint-Laurent (CA); Alexandre Gaumond, Montreal (CA); Michael Davies, Ottawa (CA)

(21) Appl. No.: 12/994,973

(22) PCT Filed: May 28, 2009
(86) PCT No.: PCT/CA09/00730

§ 371 Date: Feb. 18, 2011

Related U.S. Application Data
(60) Provisional application No. 61/056,613, filed on May 28, 2008.
(60) Provisional application No. 61/091,804, filed on Aug. 26, 2008.

(51) Int. Cl. H01L 31/032; B32B 7/02; B32B 9/04; B32B 3/00; C09D 1/00; H01L 31/0216

(52) U.S. Cl. 136/256; 428/212; 428/446; 428/215; 428/336; 106/286.8

(57) ABSTRACT

The present invention relates to an antireflective coating comprising an amorphous silicon carbide-based film, which film further comprises hydrogen atoms and optionally further comprises oxygen and/or nitrogen, the film having an effective refractive index (n) between 2.3 and 2.7 and an extinction coefficient (k) of less than 0.01 at a wavelength of 630 nm. The present invention also relates to methods for preparing the antireflective coating and to solar cells comprising the antireflective coating.

### FIELD OF THE INVENTION

This invention relates to silicon carbide-based antireflective coatings having advantageous optical characteristics, to methods for their preparation, and to solar cells comprising the coatings.

### BACKGROUND OF THE INVENTION

The efficiency (i.e. electrical power output/power input of incident useful light) of a solar cell is directly related to the amount of useful light entering the solar cell. The useful light for a given solar cell may be defined as electromagnetic energy at those wavelengths which, when absorbed by the solar cell, will result in the generation of carriers. Accordingly, the efficiency of the solar cell will depend in part on the amount of the incident light transmitted through to the cell, which transmission can be limited by the reflection and absorption of the light striking the top surface of the solar cell. To reduce this reflection, an antireflection coating (ARC), through which light enters the cell, is positioned on the surface of the solar cell. A properly functioning antireflection coating reduces reflection of the useful light while not absorbing it.

The optical properties (refractive index and extinction coefficient) required for an antireflection coating of a solar cell depend on the refractive index of the underlying substrate and, if applicable, of the encapsulated cover, as well as the wavelength response of that solar cell, in addition to the absorption of the light in the ARC film for that solar cell.

To reduce the absorption of the useful light in the ARC, a material having low absorption of useful light is needed. A low extinction coefficient (k) can be equated to a low absorption (A) (e.g. a k of less than 0.01 corresponds to absorption of less than 1%), since A=4πk/λ.

Silicon Nitride Films

ARC films have mainly been prepared using silicon nitride films (a-SiN:H). However, such films have been found to display a high absorption of incident light at high refractive index over 2.1. While there has been some success in lowering the absorbance of light in the wavelength range of 300-1200 nm at a refractive index of about 2.1, no such success has been obtained for a refractive index above 2.1. For example, while U.S. Pat. No. 5,418,019 discloses an increase in the refractive index from 2 to 3.5 for a SiN film, it fails to avoid a higher absorption loss due to the silicon-rich SiN coating. As recognized by Soppe et al. (Prog. Photovolt: Res. Appl. 2005; 13:551-569), a compromise must be made in either the extinction coefficient or refractive index when trying to simultaneously obtain high values of n and low values of k in SiN films obtained from silane and ammonia. This compromise is stated to result from Si—Si co-ordination within the film, i.e. atomic level characteristics inherent to these SiN films, when the concentration of silicon is increased (which increase is required to obtain a higher refractive index film).

Aberle et al. (Progress in Photovoltaic: Research and Applications 5, page 29-50 (1997)) also reported that SiN films deposited by different techniques for solar cell passivation purpose can lose from about 50% to almost 100% of the effective life time of the SiN films after direct exposure to UV light for 100 hours, which is equivalent to 2 years of exposure for an encapsulated solar cell.

Another issue for the application of a-SiN:H films in industrial multi-crystalline (mc) silicon solar cell production processes is the shrinkage of the ARC films after firing, a factor that alters the thickness, composition, stress, and optical properties of SiN films, which makes control of the ARC performance difficult. For example, Hong et al. (Prog. Photovolt: Res. Appl. (11)125-130 (2003)) and Jeong et al. (J. Appl. Phys., 87 (10) 7551 (2000)) reported a variation in thickness of 7 nm (which was about 10% of the film thickness) in addition to instability of the refractive index due to the firing process.

Preparation of silicon nitride films also entails safety challenges, as it requires the use of silane (SiH₄), which is pyrophoric. The process also uses, in some embodiments, oxygen in combination with silane. Presence of oxygen, however, increases the risk of an explosion. The use of H₂ can also prove challenging for safety reasons. While U.S. Pat. No. 6,060,132 to Lee discloses a chemical vapor deposition process using an ultra high vacuum of 0.1 mTorr to about 20 mTorr to reduce the risk of explosion due to mixing oxygen with silane, such a process involves additional costs.

Silicon Carbide Films

In searching for new materials for ARC applications, potential has been recognised for silicon carbide (SiC) films. The excellent mechanical properties of SiC, such as its hardness and wear resistance, are attractive for protective and tribological coatings. Further, the fact that such coatings can themselves contain the hydrogen atoms needed for bulk passivation of multicrystalline solar cells is advantageous.

However, conventional silane-based silicon carbide films do not exhibit the transmission properties necessary to achieve high efficiency solar cells, due to high absorption (high extinction coefficient) of the incident light in the film. Consequently, such absorption causes critical limitations such as (a) failure of the light to reach the solar cell, (b) generation of heat in the ARC layer which degrades the ARC and the solar cell quality thus reducing the efficiency of the solar cell, (c) instability of the electrical properties of the cell, and (d) potential degradation of the lifetime of the solar cell. These problems become particularly acute when designing solar cells for use in harsh environments, such as for satellite solar cells.

In fact, silicon carbide's high absorption of light and high extinction coefficient has made it an attractive candidate for use in damascene interconnection structures as a capping layer/bottom antireflection coating (BARC). Such a high extinction coefficient is highly desirable in BARC applications, such as gate formation, where dimension control is important. Subramanian et al. (U.S. Pat. No. 6,465,889 and U.S. Pat. No. 6,656,830) teach the use of SiC as BARC with an extinction coefficient (k) of about 0.1 to about 0.6. US Patent Application No. 20030211755 to Lu, et al. also teaches a process of exposing the ARC dielectric material to plasma treatment of the surface after each sub layer deposition. In their process a k value of 0.4-0.6 was achieved.

While several attempts have been made to reduce the extinction coefficient of SiC films, these attempts not only failed in achieving adequate reductions but also imposed new challenges and limitations. YANG et al. (Mat. Res. Soc. Symp. Proc. Vol. 715 page A24.3.1, 2002) teach a technique of reducing the extinction coefficient and the refractive index of SiC by increasing the deposition temperature. In their study, they achieved a reduction of the extinction coefficient from about 0.31 to about 0.1. However, even these limited reductions were accompanied by several challenges including the use of a deposition temperature of 650° C., which is too high to be used in optoelectronic applications as at such temperature inter-diffusion of dopants is expected. While high temperatures can be utilised during the preparation of optoelectronic devices such as solar cells (e.g. a firing process), these high temperatures are generally maintained only for a few seconds of time, limiting dopant inter-diffusion. Further, the pulsed laser deposition (PLD) technique used by Yang et al. is well known to produce films deficient in hydrogen, and said deficiency can prove critical since hydrogen is an element significant for ARC films used in the solar cell industry, specifically for multicrystalline solar cells where hydrogen is expected to passivate the surface and the bulk of the solar cell.

Gallis et al. (J. Appl. Phys. 102, 024302 (2007)) disclose a silicon carbide-based film wherein the absorption coefficient (α) is 5000 cm⁻¹ (which equals to an extinction coefficient (k) of 0.025 at wavelength (λ) of 632 nm) and the refractive index is 1.8, for SiOC, and the α is 8000 cm⁻¹ (k=0.04 at wavelength (λ) of 632 nm) and n is 2.6 for a-SiC film.

Klyuia et al. (Solar Energy Materials & Solar Cells 72, 597-603 (2002)) teach optical properties of amorphous silicon carbide having an extinction coefficient of about 0.01, and a refractive index of about 1.97. C. H. M. van der werf et al. (Thin Solid Films, 501, 51-54 (2006)) also report a low extinction coefficient of 0.001, but this is only achieved in a film of refractive index of 1.9. To achieve higher refractive index of 2.5, the extinction coefficient was increased to 0.1. Such increase in the extinction coefficient is expected to increases the light energy loss up to 15% due to absorbance of the ARC film.

Shaaban et al. (Phys. stat. sol. (a) 195 (1) 277-281 (2003)) studied amorphized crystalline silicon carbide, and reported an extinction coefficient of about 0.5, and a refractive index of about 3.05 at a wavelength λ=630 nm. Another reference referring to SiC is U.S. Pat. Application No. 20050230677 to Wetzel et al., wherein Wetzel refers to a specific formation of SiC wherein the refractive index is 1.40<n<2.60, and the extinction coefficient is approximately 0.01<k<0.78. However, the lower values for the extinction coefficient were only obtained at a lower refractive index.

Lipinski et al. (Phys. Stat. Sol. (c) 4, No. 4, 1566-1569 (2007)) reported a graded index SiOₓN_{y} antireflection coating. Again, when an effective reflectance (i.e. average reflectivity from 250 to 1200 nm) of 2.52% was achieved, the effective absorption of 9.43%, due to the high extinction coefficient, could not be reduced. As a result, the achieved low reflectance was negated by the high absorption.

The requirements of high refractive index and low extinction coefficient mentioned above make the development of a suitable antireflection coating for use in solar cells difficult. Thus, there exists a strong need for the development of an antireflection coating, for use in solar cells, which combines all the requirements and reduces or eliminates most if not all the limitations.

### BRIEF SUMMARY OF THE INVENTION

In one aspect, the present invention provides an antireflective coating comprising an amorphous silicon carbide-based film, which film further comprises hydrogen atoms and optionally further comprises oxygen and/or nitrogen, the film having an effective refractive index (n) between about 2.3 and about 2.7 and an extinction coefficient (k) of less than about 0.01 at a wavelength of 630 nm.

In another aspect, the present invention provides a method for forming the antireflective coating of the invention, comprising depositing on a substrate organosilanes, organopolycarbosilanes or a combination thereof, obtained from pyrolysis of a solid organosilane source.

In another aspect, the present invention provides a gas mixture comprising up to 80 wt. % methylsilane, up to 85 wt. % dimethylsilane, from 5 to 45 wt. % trimethylsilane, up to 10 wt. % tetramethylsilane, up to 35 wt. % 1,1,2-trimethylcarbodisilane, up to 20 wt. % 1,1,2,2,-tetramethycarbodisilane, and up to 10 wt. % 1,1,1,2,2-pentamethylcarbodisilane.

In still another aspect, the present invention provides a gas mixture comprising up to 10 wt. % methylsilane, up to 15 wt. % dimethylsilane, from 5 to 45 wt. % trimethylsilane, up to 10 wt. % tetramethylsilane, from 10 to 35 wt. % 1,1,2-trimethylcarbodisilane, from 2 to 20 wt. % 1,1,2,2,-tetramethycarbodisilane, and up to 10 wt. % 1,1,1,2,2-pentamethylcarbodisilane.

In yet another aspect, the present invention provides a gas mixture comprising from 20 to 45 wt. % methylsilane, from 35 to 65 wt. % dimethylsilane, from 5 to 15 wt. % trimethylsilane, and optionally up to 10 wt. % gaseous carbosilane species.

The above and other features and advantages of the present invention will become apparent from the following description when taken in conjunction with the accompanying figures which illustrate preferred embodiments of the present invention by way of example.

### BRIEF DESCRIPTION OF THE DRAWINGS

Embodiments of the invention will be discussed with reference to the following Figures:

FIG. 1 displays a PC-1D simulation of the effect of refractive index on the efficiency of a solar cell coated by an ARC. The cell is modelled as if in direct contact to air;

FIG. 2 displays a PC-1D simulation of the effect of refractive index on the efficiency of a solar cell coated by an ARC. The cell is modeled as if in a module covered by 3 mm thick glass;

FIG. 3 graphs the theoretical absorption and reflection percentage as a function of extinction coefficient of dielectric thin films. R is reflection, T is transmission and A is absorption;

FIG. 4 provides a comparison of the relationship between the extinction coefficient and refractive index for thin films of the prior art and embodiments of the present invention;

FIG. 5 shows the correlation between the refractive index (n) and the extinction coefficient (k) of a-SiCH films with respect to light wavelength. Measurements were made by spectroscopic ellipsometry;

FIG. 6 shows the refractive index of a-SiCH:N films with respect to light wavelength. Measurements were made by spectroscopic ellipsometry;

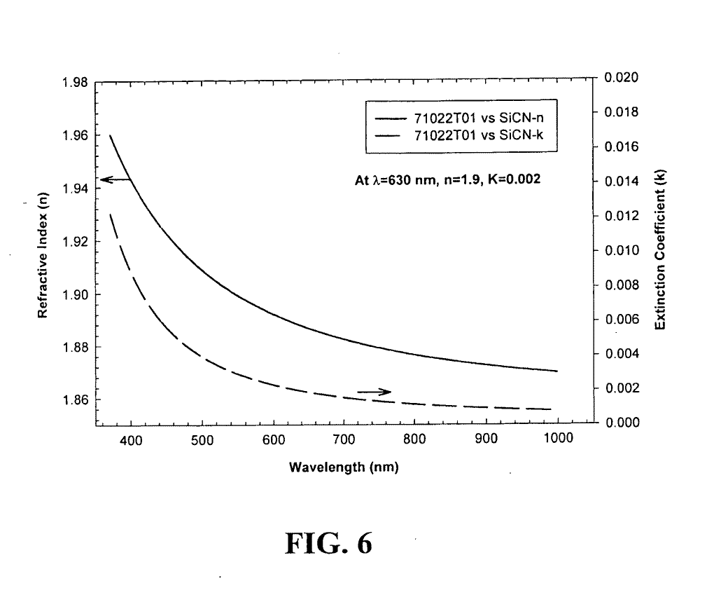

FIG. 7 shows the refractive index and extinction coefficient of a-SiOC films prepared by PECVD. Measurements were made by spectroscopic ellipsometry;

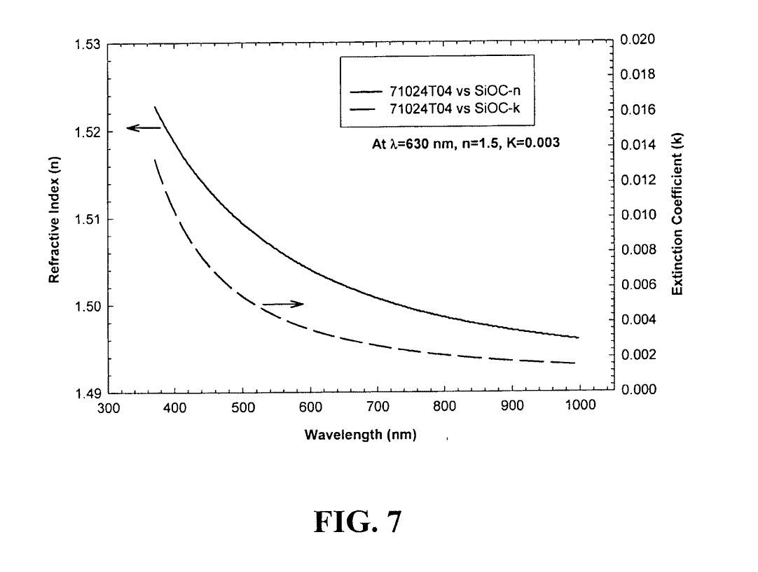

FIG. 8 compares the absorption coefficient of a-SiC films of the invention with other SiC and SiCN and SiN films reported in the literature (Soto et al., J. Vac. Sci. Technol. A 16 (3), 1311 (1998); Lauinger et al., J. Vac. Sci. Technol. A 16 (2)530(1998); Conde et al., J. Appl. Phys. 85 (6) 3327 (1999); Moura et al., Surface and Coatings Technology 174-175, 324-330 (2003));

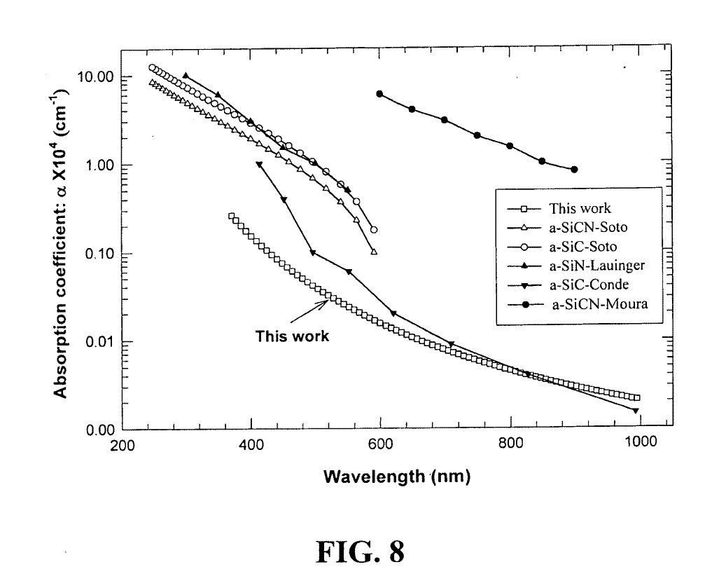

FIG. 9 compares the reflectivity of single layer a-SiCH:N ARC films at different composition & thickness. The “R” value refers to the average reflectivity over the wavelength range 400-1200 nm;

FIG. 10 displays an Elastic Recoil Detection (ERD) depth profile of a-SiCH films at 400° C. The Silicon, Carbon, Nitrogen, Oxygen, Hydrogen concentration is presented as atomic concentration, total=100%;

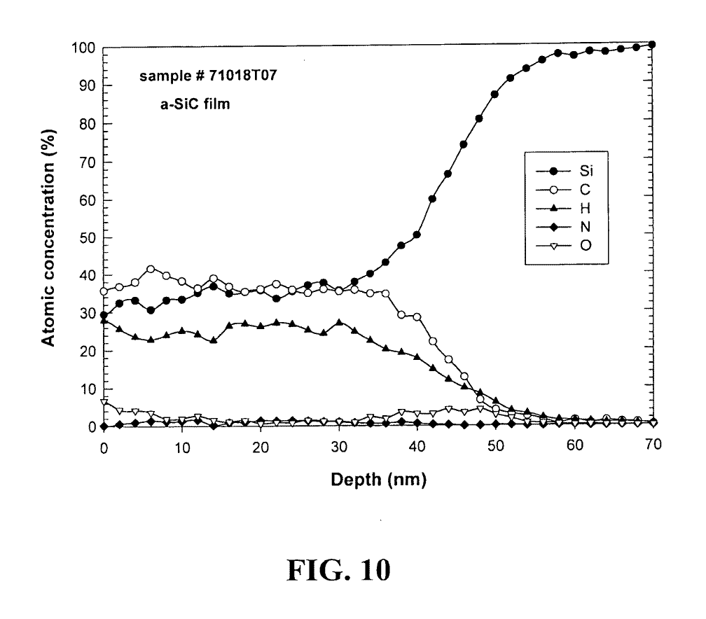

FIG. 11 graphs the stress of a four micron thick a-SiCH film as a function of annealing temperature. This film was specifically prepared to facilitate the measurement of stress;

FIG. 12a displays a wafer map of carrier lifetime as measured by a Semilab μPCD tool. The map data is also presented as a histogram in FIG. 12b. The film is SiCN deposited by PECVD on a float zone (FZ) 5,000 Ohm·cm, N-type Si substrate. The median carrier lifetime is shown to be about 1,700 μseconds;

FIG. 13 graphs the refractive index of a-SiCH deposited on Si (100) substrate before and after rapid thermal annealing (RTA) at different temperature for 5 sec peak time. The ramp up and cooling down temperature is 25° C./sec;

FIG. 14 graphs the refractive index of a-SiCH:N deposited on Si (100) substrate before and after rapid thermal annealing (RTA) at different temperature for 5 sec peak time. The ramp up and cooling down temperature is 25° C./sec;

FIG. 15 graphs the extinction coefficient of a-SiCH deposited on Si (100) substrate before and after rapid thermal annealing (RTA) at different temperature for 5 sec peak time. The ramp up and cooling down temperature is 25° C./sec;

FIG. 16 graphs the extinction coefficient of a-SiCH:N film deposited on Si (100) substrate before and after rapid thermal annealing (RTA) at different temperature for 5 sec peak time. The ramp up and cooling down temperature is 25° C./sec;

FIG. 17 graphs the thickness a-SiCH film deposited on Si (100) substrate before and after rapid thermal annealing (RTA) at different temperature for 5 sec peak time. The ramp up and cooling down temperature is 25° C./sec;

FIG. 18 graphs the thickness of a-SiCH film deposited on Si (100) substrate before and after rapid thermal annealing (RTA) at different temperature for 5 sec peak time. The ramp up and cooling down temperature is 25° C./sec;

FIG. 19 displays a scanning electron micrograph of a pyramidal peak on a textured solar cell surface prepared by PECVD;

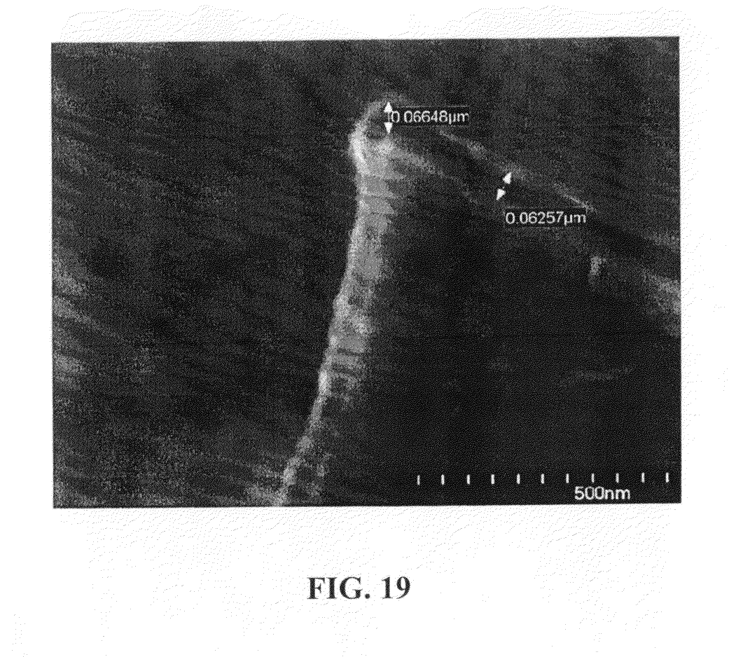

FIG. 20 displays life time and saturated current density (Jo) of a-SiCN films on float zone (FZ) n-type Si (100) as a function of annealing temperature;

FIG. 21 displays the solar spectrum intensity as a function of wavelength;

FIG. 22 displays silicon PN junction responsivity;

FIG. 23 displays a micrograph of a scratch track obtained, for a SiC film, from a Micro Scratch Tester at different loads;

FIG. 24 graphs the refractive index and extinction coefficient of a-SiCH:N samples prepared with various concentrations of NH₃ gas.

FIGS. 25a-d displays the effect of double antireflection layer (DARC) on solar cell parameters: short circuit current (Jsc), open circuit voltage (Voc), fill factor (F.F.) and conversion efficiency (Eff.). Solar cell parameters of DARC are compared with solar cells with single antireflection layers (SARC 1-4) having varying refractive indices.

### DETAILED DESCRIPTION OF THE INVENTION

Optical Properties

The purpose of an antireflective (ARC) coating is to reduce or eliminate any reflected light waves, typically by adjusting three aspects of the ARC material: the refractive index (n), the extinction coefficient (k) (also referred to as the absorption index), and the thickness (t) of the ARC, to create a phase cancellation and absorption of reflected light. Typically, the required n, k, and t values depend on the thickness and properties of the underlying substrate and need adjustment for each particular application.

The ARC film produced by the present invention has a tunable refractive index and extinction coefficient which can be optionally multilayered or graded along the film thickness to match the optical properties of the substrate and the encapsulated cover. These ARC materials significantly decrease light absorption and reflection at wavelengths of 300-1200 nm, which is consequently expected to provide significantly higher useful light transmission and improvement of solar cell efficiency.

Criticality of n and k

As a fundamental optical property, the antireflection coating should reduce reflection of the useful light. Further, in order to efficiently use a solar cell bearing the film, it would be best to employ an antireflection coating that does not absorb light (i.e. k=0) across the entire useful spectrum, e.g. between 300-1200 nm. Generally, the optimum refractive index (n) of a single ARC film can be calculated as follows:

n=\sqrt{n1.n3}

where n1 and n3 are the refractive indices of the encapsulating layer and the substrate, respectively. The optimum thickness (t) of the film can also be calculated as follows:

$$t = \frac{{λ}_{c}}{4 \cdot n}$$

where λ_{c} is the central wavelength at which the reflection of light is minimum (R≈0).

The finished films can be single layers with single n and k values, multiple layers with distinct n and k values, or a graded film having a gradient of n and k values. For embodiments where multiple layers having different n values are combined or for graded films, the resulting combined refractive index is referred to as the “effective” refractive index.

Software simulation (PC-1D) can be used to determine the precise thickness for each sub-layer as well as the optical properties (n, k and reflectance(R)) of the ARC film. In-situ or ex-situ measurements of n, k and R of each layer can be used as a feedback tool to guide conditions for deposition of single or multiple layers.

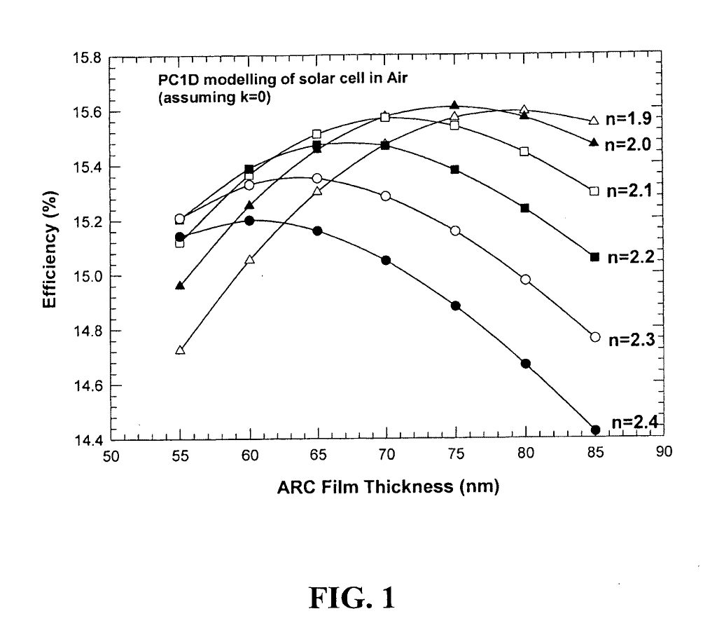

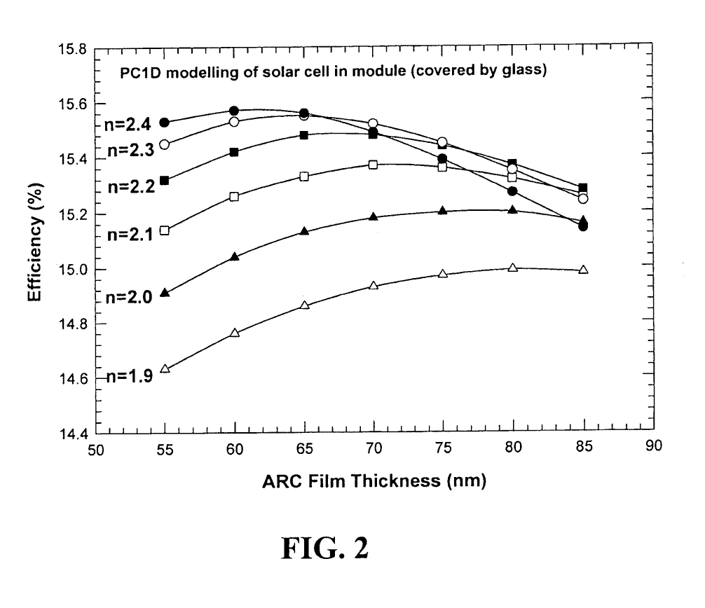

FIGS. 1 and 2 display results from PC-1D software simulations of solar cell efficiency in air (FIG. 1) and in a glass-covered module (FIG. 2). Both simulations assume that the absorption of light in the film is zero (i.e. k=0). Other assumptions are provided in Table 1:

TABLE 1

| Device Parameter | Input |
|---|---|
| Base resistivity (Ω · cm) | 1.5 |
| Thickness | 300 |
| Front Surface Recombination Velocity | 10⁵ cm/sec |
| (FSRV) | |
| Grid coverage | 3.5% |
| Front surface coating | SiCN, n = 1.9 |
| Rear Internal Reflectance | 70% |
| Front doping | 2.8E20 cm⁻³ |
| Base contact (series resistance) | 6*10⁻³ Ω |
| Internal conductor (shunt resistance) | 0.3 S |
| Bulk lifetime (μs) | 30 |
| Back Surface Recombination Velocity | 10⁵ cm/sec |
| (BSRV) | |

As shown in FIG. 1, the maximum efficiency is obtained when the index of the film is about 2.0 and the thickness is 75 nm. However, when this film-coated cell is encapsulated into a module, i.e. covered with a glass plate of refractive index ˜1.5, it can be seen that the cell now loses about an additional 0.4% of absolute efficiency (bottom curve in FIG. 2). However, if the coating has a higher refractive index (i.e. n ˜2.4) and if the thickness is modified to 60 nm, the loss due to encapsulation is eliminated and a small improvement is possible (with the assumption that k remains 0). Accordingly, an optimum single ARC layer for a silicon based solar cell encapsulated in glass (e.g. quartz, boro-silicate or soda glass) should have a refractive index of about 2.35, while the graded refractive index in a single layer or multilayers ARC can be in the range of 1.5-3.85 to achieve an effective refractive index about 2.35.

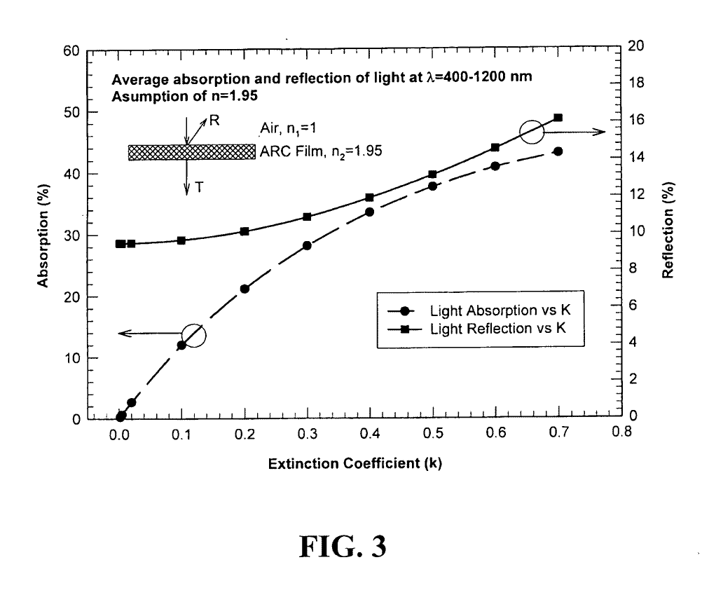

For a film of a given index n bounded on both sides by air with a refractive index of 1, the dependence of light reflection, absorption and transmission on k is calculated according to equations below and the result is presented in FIG. 3.

For normal incidence, the reflectance of light is calculated according to

$$R = \frac{[ {( n - 1 )}^{2} + {k}^{2} ]}{[ {( n + 1 )}^{2} + {k}^{2} ]}$$

Where n is the refractive index, k is the extinction coefficient, related to the absorption coefficient by the relationship:

$$k = \frac{αλ}{4 π}$$

The transmission of light is calculated by:

T=(1−R)e^{-α.d}

Then the absorption is calculated by:

1=T+R+A

FIG. 3 shows the impact of the total absorption and reflection of a free standing film as a function of k. As can be seen from FIG. 3 if k is >0.1 then the film is highly absorbing, rendering films of high k inappropriate for solar cell anti-reflecting coatings.

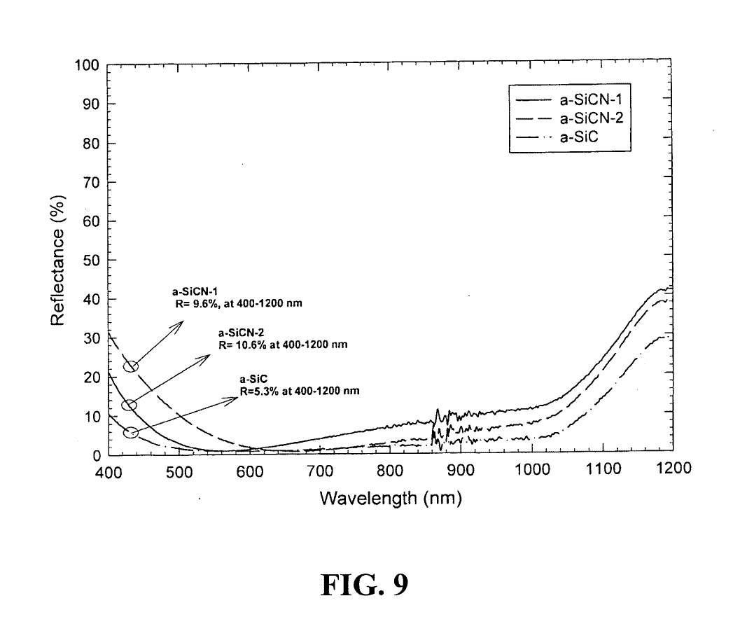

The reflectance of non-encapsulated a-SiCH:N films of different thickness are shown in FIG. 9, where it can be seen that the reflectance is driven to zero at certain wavelengths, indicating a good match between the Si substrate, the a-SiCH:N film and air. As noted above, this reflectance can be further suppressed by putting a λ_{c}/4n thick SiOC layer, whose refractive index is 1.5, on top of the a-SiCH:N Layer.

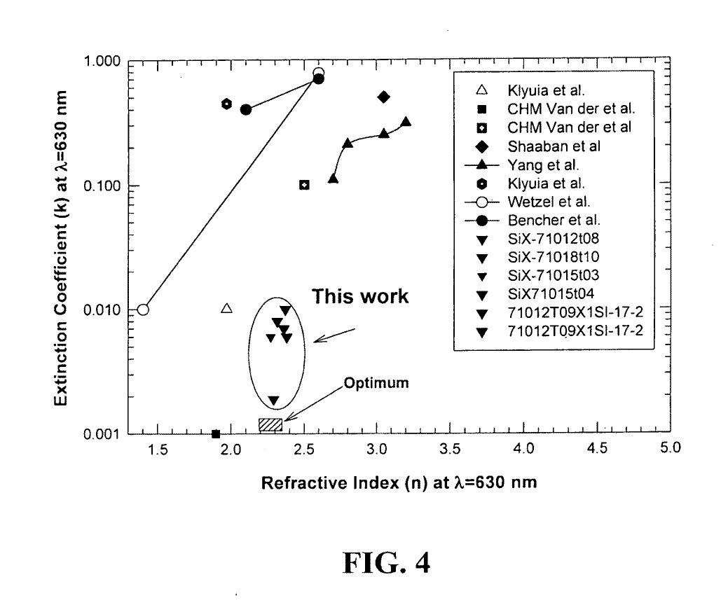

FIG. 4 compares the optimum n and k values for antireflective coatings in encapsulated solar cells, as detailed above, with corresponding values in ARC films known in the art and ARC films prepared according to the present invention. It is clear from this figure that the films of the present application are substantially closer to the optimum values than the previously known films.

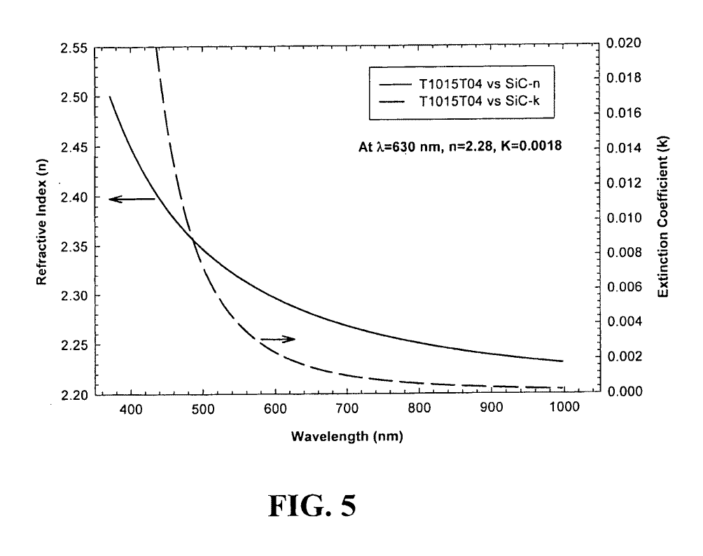

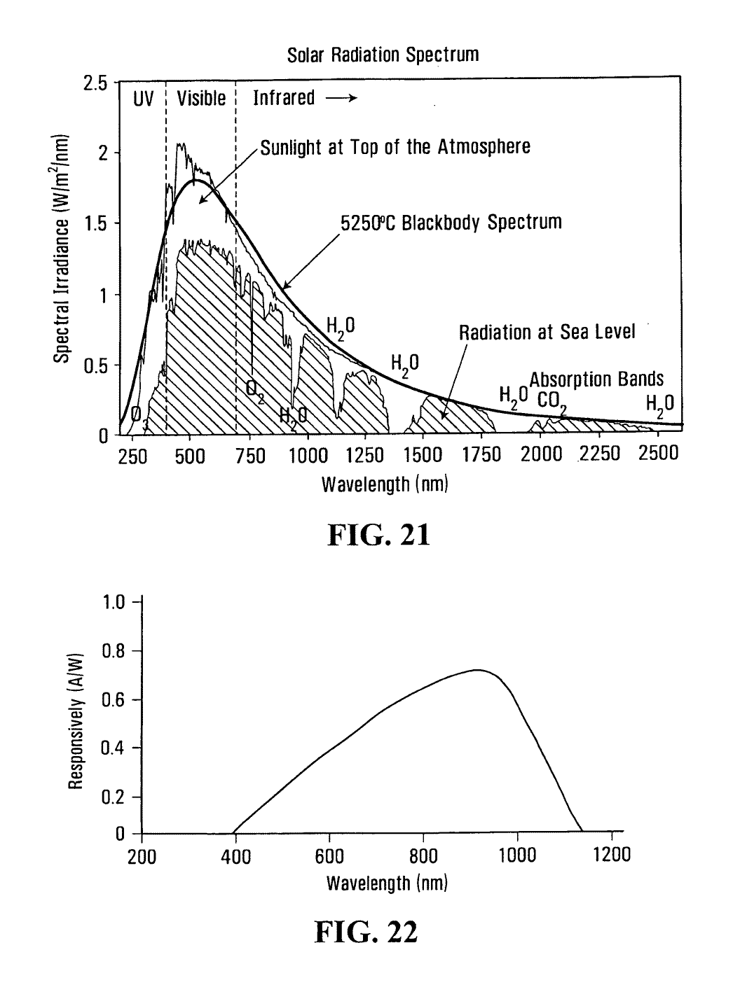

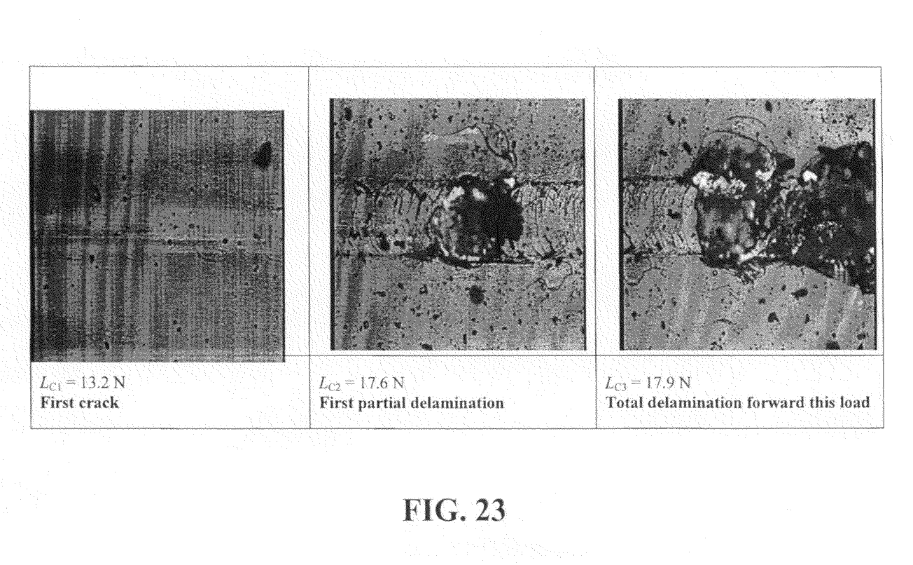

FIG. 5 shows the correlation between the refractive index (n) and the extinction coefficient (k) of a-SiCH films with respect to light wavelength. This figure allows determination of the refractive index and extinction coefficient at specific wavelengths. The importance of these wavelengths can be seen in FIG. 21, which provides the solar spectrum intensity as a function of wavelength. Further, as can be seen in FIG. 22, the maximum responsivity (ability to generate electron-hole pairs from the absorption of photons) for a Silicon PN junction is at a wavelength about 850 nm. Since (a) the maximum solar intensity is at ˜510 nm and the maximum solar cell responsitivity is at 850 nm, the typical design compromises and the reflection minimum of an ARC on a solar cell is ˜600-630 nm. This minimum is determined by the optical thickness, the combination of the refractive index and physical thickness. For a given optical thickness, a thinner layer is required with higher index materials.

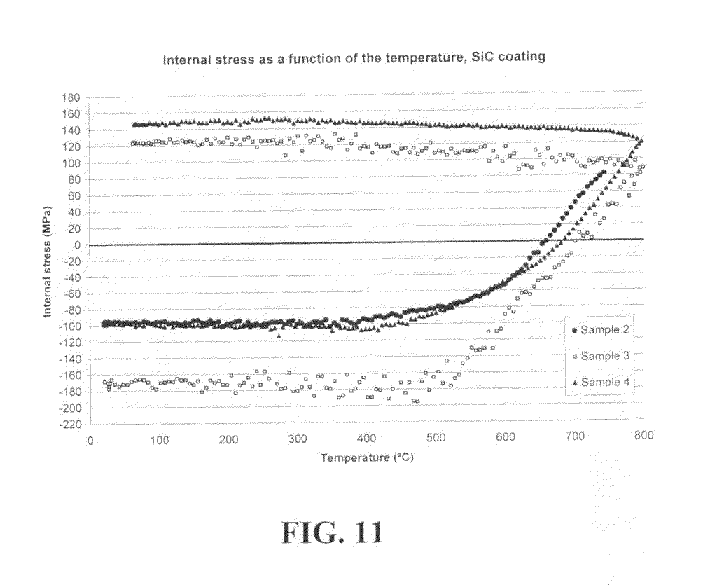

FIG. 11 displays a scanning electron micrograph of a peak on a textured solar cell surface prepared by PECVD. The wafer is cleaved through the peak to determine how conformal the ARC deposited by PECVD is on the textured surface. The thickness on the peak and the sidewall are very similar, confirming the presence of a good conformal coating. Good conformal coverage indicates that the ARC film exists at the right thickness, irrespective of the incident angle of the light, to ensure that reflection is reduced.

ARC Film Composition

In one embodiment, the present invention describes a thin film comprising amorphous silicon carbide, which film comprises hydrogen and optionally further comprises oxygen and/or nitrogen. These films are also referred herein as a-SiCH:X films, wherein X can represent nitrogen and/or oxygen. Examples of a-SiCH:X films include amorphous silicon carbide, amorphous silicon carbonitride, amorphous silicon oxycarbonitride or amorphous silicon oxycarbide films.

The thin film provides high refractive index values while maintaining an extinction coefficient below 0.01. In one embodiment, the film has an effective refractive index (n) between about 2.3 and about 2.7 and an extinction coefficient (k) of less than about 0.01 at a wavelength of 630 nm. In another embodiment, the antireflective coating can have an effective refractive index (n) between about 2.3 and about 2.4, for example about 2.35. In still another embodiment, the extinction coefficient (k) can be less than about 0.001.

In one embodiment, the atomic % range for Si in the film is from 30% to 70%, for example greater than 35% to 60%, from 40% to 60%, from 45 to 55% or about 50%.

In another embodiment, the atomic % range for C in the film is from 3% to 60%, for example from 10% to 50%, from 20 to 40%, or from 25 to 35%.

In another embodiment, the atomic % range for H in the film is from 10% to 40%, for example from 15% atomic % to 35%, from 20 to 30% or from 22 to 28%.

In another embodiment, the atomic % range for N in the film is from 0% atomic % to 50%, for example from 10% to 45%, from 20 to 40%, or from 25 to 35%. In some embodiments, increase in nitrogen concentration leads to an increase in the refractive index.

In another embodiment, the atomic % range for O in the film is from 0% to 50%, for example from 10% to 40%, from 20 to 30%, or from 22 to 28%. In some embodiments, increase in oxygen concentration leads to a decrease in the refractive index.

In a further embodiment, the film can also comprise other atomic components as dopants. For example, the doped-film can also comprise F, Al, B, Ge, Ga, P, As, N, In, Sb, S, Se, Te, In, Sb or a combination thereof.

The thickness of the film can be selected based on the other optical and physical characteristics desired for the prepared ARC. In one embodiment, the thickness is selected in order to obtain a reflection minima at around 600-650 nm. For example a refractive index of 2 with a thickness of 75 nm can be considered optimum, as shown in FIG. 1, although small variations in thickness, e.g. 5 nm, may not greatly affect the refractive index. In one embodiment, the finished film will have thickness from about 50 to about 160 nm, e.g. from about 50 to about 100 nm or from about 70 to about 80 nm.

Stability of the ARC Film

The optical (n, k, R), and physical (thickness) properties of the films of the present invention show very high stability after exposure to high temperature processing.

Optical Stability

The stability of the optical properties of the ARC film after firing is an important quality. Specifically, the stability of optical properties (n,k) after high temperature firing, which is carried out in the solar cell fabrication, is advantageous. Stability of the thickness of the ARC after high temperature firing is also useful. Firing temperatures can be selected, for example, to be from 700 to 900° C., and firing can be carried out for e.g. 1 to 15 seconds. In one embodiment, firing is carried out a temperature of from 850-875 C for less than a few seconds.

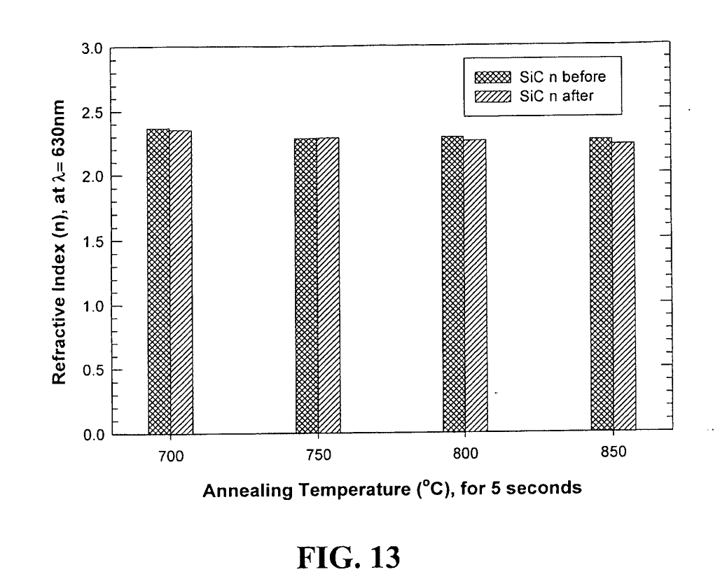

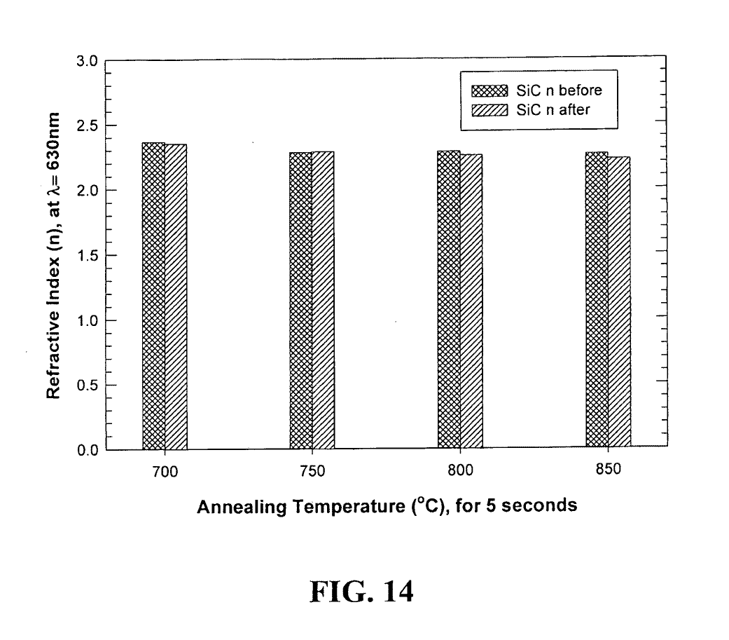

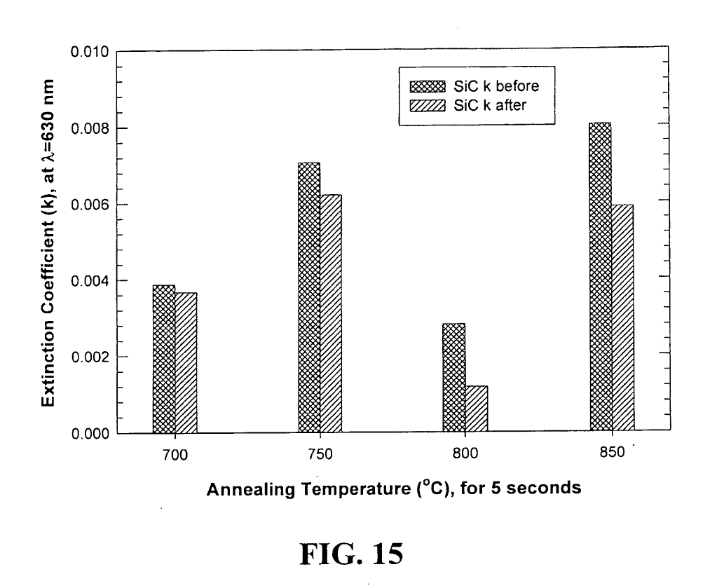

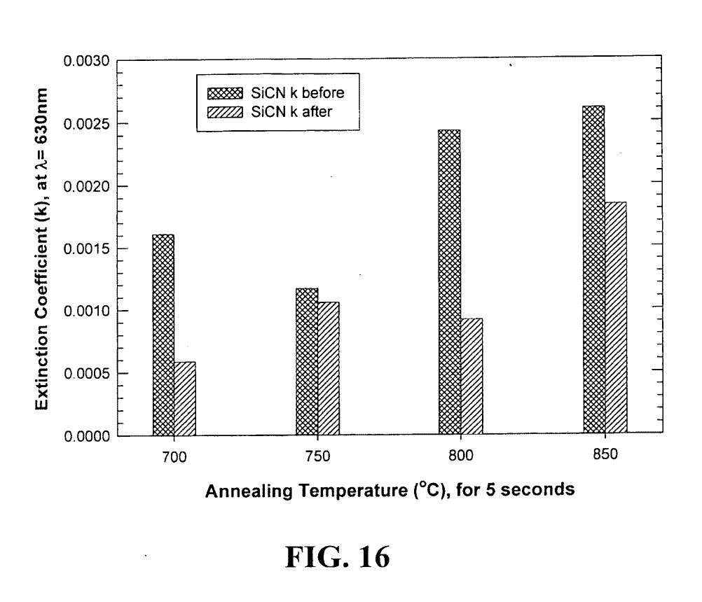

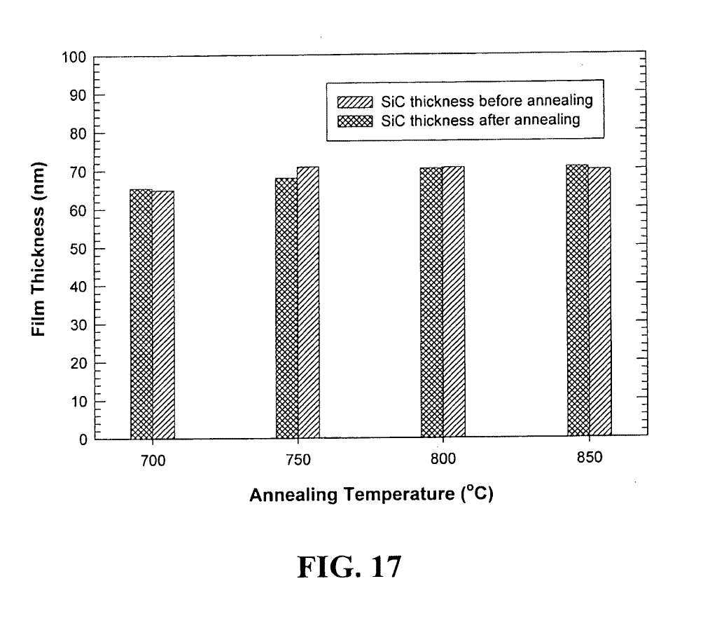

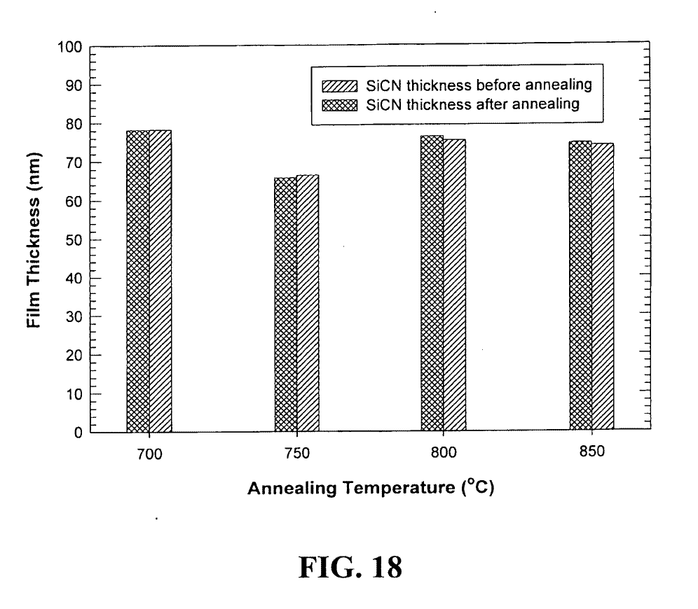

As displayed in FIGS. 13 and 14, a-SiC and a-SiCN films according to the present invention maintain stable refractive index values when annealed at temperatures from 700 to 850° C. Further, the extinction coefficient of these films can be improved (i.e. be lowered) when annealed (FIGS. 15 and 16). Stability in thickness is also observed for these films (FIGS. 17 and 18). The stability of the optical thickness is of greatest import, i.e. if the thickness goes down and the index of film goes up the overall optical thickness can remain the same. Firing conditions may be deliberately designed to obtain shrinkage in the thickness, which likely causes densification of the film-and an associated increase in refractive index.

Structural and Chemical Stability

In terms of mechanical properties, the antireflection material should be hard enough so that it will not be damaged during manufacture or use, particularly during cover slide attachment. The antireflection material should also be chemically stable in that it should not change composition and should maintain constant properties during processing, where it may be exposed to temperature, chemicals and moisture, or during shelf storage. The present use of silicon carbide-based films is advantageous in this regard, as such films are known to have excellent hardness and wear resistance. In one embodiment, the hardness of the film can be from 5-20 Gpa, e.g. from 15-18 GPa.

Further, the mechanical stress produced at the antireflection coating/semi-conductor interface should be small so that such stress will not damage the junction. As displayed in FIG. 11, low stress silicon carbide-based films of the invention were deposited at a substrate temperature of 400° C. in a plasma enhanced chemical vapor deposition (PECVD) unit. The stress distributions were studied by way of a slow thermal cycle from room temperature to 800° C. and then cooling back to room temperature. As can be noted, as-deposited the films have a stress of −(100 to 180) MPa, the stress goes through zero as the sample is heated and then the residual stress is +(120 to 140) MPa after cooling. The stress could be further reduced to achieve a stress-free film (i.e. a film with a stress value of less than 20 MPa) by post deposition annealing and shifting from the compressive region to the tensile region. The stress relaxation can be ascribed to the dissociation of the hydrogenated bonds and the incorporation of hydrogen. As a result, Si—C bonds were created, leading to the formation of tensile stress. In one embodiment, the stress of the film is less than 150 MPa, preferable less than 90 MPa.

The adhesion of the antireflection coating to the solar cell should also be sufficient so as to ensure that delamination does not occur during processing or exposure to moisture or temperature cycling. Procedures for determining adhesion are set out in Example 8.

Passivation

It is also important for the long-term stability of the efficiency of a solar cell that the surface passivation capability of the solar cell does not degrade under extended exposure to sunlight. The ARC should therefore be able to passivate defects in the surface of the substrate (e.g. saw damage; etch damage, dangling bond, etc.). Poorly passivated surfaces reduce the short circuit current (Jsc), the open circuit voltage (Voc), and the internal quantum efficiency, which in turn reduces the efficiency of the solar cell. The ARC film can reduce the recombination of charge carriers at the silicon surface (surface passivation), which is particularly important for high efficiency and thin solar cells (e.g. cells having a thickness <150 μm). Bulk passivation is also important for multicrystalline solar cells, and it is believed that high hydrogen content in the ARC film can induce bulk passivation of various built-in electronic defects (bulk impurities/defects, grain boundaries, etc.)in the multicrystalline (mc) silicon bulk material.

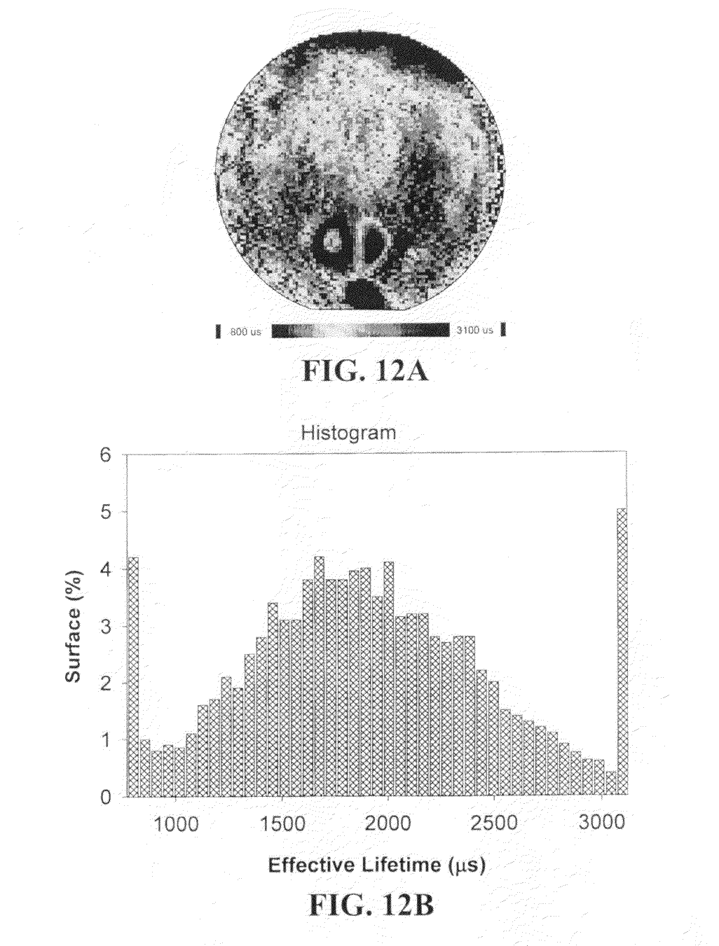

The films of the present invention are advantageous as they naturally contain the hydrogen atoms, which can impart good passivation characteristics to the ARC film. From FIG. 12, it can be seen that the median carrier lifetime of a SiC film deposited by PECVD is about 1,700 μseconds. When this carrier lifetime is converted to surface recombination velocity (SRV), it is clear that the passivation results are more than sufficient to achieve the surface recombination requirements for Silicon-based solar cells, which typically require a SRV less than 10,000 cm·s−¹.

Benefits of the ARC Films

The ARC films of the invention have been found to be superior to the silane-based ARC Si₃N₄ materials. Unlike conventional SiN films, the present films have a controllable refractive index in the range of about 1.5 to about 2.7 yet keeping the extinction coefficient below 0.01, which corresponds to absorption losses of less than 1%. This low absorption loss is important for solar cells, including those that are covered e.g. by glass.

The ability to tune the refractive index in a wide range without increasing the absorbance also enables the use of the present films in the preparation of graded refractive index single or multilayer ARC structures. The films of the present invention also permit the combination of a-SiCH, a-SiCH:N, and a-SiCH:O layers in a multilayer structure that may combine functions of ARC coating, surface passivation, dielectric structure, environmental protection and hydrogen reservoir for bulk passivation. The present films are also advantageous over the known SiN films in that they maintain stable refractive index and extinction coefficient after firing (Δn<1% abs of the a-SiCH:X of the current inventions compared to about 10% of conventional SiN films), and they maintain a stable thickness after processing at high temperatures (Δt<2% compared to about 10% of conventional ARC films).

The present ARC films can also be prepared without the use of SiH₄ or hydrogen gases, which proves beneficial in terms of safety, ease of control, and costs. Optionally, SiH₄ or hydrogen gases may be used in addition.

Preparation of the ARC Films

In one embodiment, the invention provides a process for preparing ARC films of the invention, which process uses an organosilane as a silicon, carbon and hydrogen source, independently of any other silicon, carbon, or hydrogen sources necessary to produce the ARC films.

In one embodiment, the antireflective coating is formed by depositing, on a substrate, organosilanes, organopolycarbosilanes, or a combination thereof obtained from thermal decomposition/rearrangement (i.e. pyrolysis) or volatilisation of a solid organosilane source. In a further embodiment, the organosilanes, organopolysilanes or combination thereof obtained from the pyrolysis are gaseous in nature and the depositing step is carried out by energy induced chemical vapour deposition. Other processes for the deposition of the organosilanes and organopolycarbosilanes on the substrate, such as spin coating, spray coating and electrostatic deposition of a liquid or liquid/gas mixture obtained from the pyrolysis of the solid organosilane source, followed by a firing step to form an ARC film, also form part of the present invention. Yet another process embodied by the invention comprises the deposition of the organosilane source in volatilised form onto a substrate to form a coating, which coating is then fired to form an ARC film.

Energy Induced Chemical Vapour Deposition

In one embodiment, the ARC film can be prepared by energy enhanced chemical vapour deposition of gaseous precursor species obtained by the pyrolysis of a solid organosilane source.

Solid Organosilane Source

A solid organosilane source refers to compounds that comprise Si, C and H atoms, and that are solid at room temperature and pressure.

The solid organosilane source may, in one embodiment, be a silicon-based polymer comprising Si—C bonds that are thermodynamically stable during heating in a heating chamber. In one embodiment, the silicon-based polymer has a monomeric unit comprising at least one silicon atom and two or more carbon atoms. The monomeric unit may further comprise additional elements such as N, O, F, or a combination thereof. In another embodiment, the polymeric source is a polysilane or a polycarbosilane.

The polysilane compound can be any solid polysilane compound that can produce gaseous organosilicon compounds when pyrolysed, i.e. chemical decomposition of the solid polysilane by heating in an atmosphere that is substantially free of molecular oxygen. In one embodiment, the solid polysilane compound comprises a linear or branched polysilicon chain wherein each silicon is substituted by one or more hydrogen atoms, C₁-C₆ alkyl groups, phenyl groups or —NH₃ groups. In a further embodiment, the linear or branched polysilicon chain has at least one monomeric unit comprising at least one silicon atom and one or more carbon atoms. In another embodiment, the linear or branched polysilicon chain has at least one monomeric unit comprising at least one silicon atom and two or more carbon atoms.

Examples of solid organosilane sources include silicon-based polymers such as polydimethylsilane (PDMS) and polycarbomethylsilane (PCMS), and other non-polymeric species such as triphenylsilane or nonamethyltrisilazane. PCMS is commercially available (Sigma-Aldrich) and it can have, for example, an average molecular weight from about 800 Daltons to about 2,000 Daltons. PDMS is also commercially available (Gelest, Morrisville, Pa. and Strem Chemical, Inc., Newburyport, Mass.) and it can have, for example, an average molecular weight from about 1,100 Daltons to about 1,700 Dalton. PDMS is known as a polymer able to yield polycarbosilane. Use of PDMS as a source compound is advantageous in that (a) it is very safe to handle with regard to storage and transfer, (b) it is air and moisture stable, a desirable characteristic when using large volumes of a compound in an industrial environment, (c) no corrosive components are generated in an effluent stream resulting from PDMS being exposed to CVD process conditions, and (d) PDMS provides its own hydrogen supply by virtue of its hydrogen substituents and yields dense amorphous SiC at temperatures as low as 50° C.

In another embodiment, the solid organosilane source may have at least one label component, the type, proportion and concentration of which can be used to create a chemical “fingerprint” in the obtained film that can be readily measured by standard laboratory analytical tools, e.g. Secondary Ion Mass Spectrometry (SIMS), Auger Electron Spectrometry (AES), X-ray photoelectron spectroscopy (XPS). In one embodiment, the solid organosilane source can contain an isotope label, i.e. a non-naturally abundant relative amount of at least one isotope of an atomic species contained in the solid organosilane source, e.g. C¹³ or C¹⁴. This is referred to herein as a synthetic ratio of isotopes.

Formation of the Gaseous Precursor Species

In one embodiment, the gaseous precursor species are formed by pyrolysis in a heating chamber. The solid organosilane source may be added to the heating chamber in a batch or continuous manner as a powder, pellet, rod or other solid form. Optionally, the solid organosilane source may be mixed with a second solid polymer in the heating chamber. In batch addition, the solid organosilane source compound may be added, for example, in an amount in the range of from 1 mg to 10 kg, although larger amounts may also be used.

In one embodiment the heating chamber is purged, optionally under vacuum, after the solid organosilane source has been added to replace the gases within the chamber with an inert gas, such as argon or helium. The chamber can be purged before heating is commenced, or the temperature within the chamber can be increased during, or prior to, the purge. The temperature within the chamber during the purge should be kept below the temperature at which evolution of the gaseous precursor species commences to minimise losses of product.

The production of the gaseous precursor from the solid organosilane source is achieved through a pyrolysis step, which can encompass one or more different types of reactions within the solid. The different types of reactions, which can include e.g. decomposition/rearrangement of the solid organosilane into a new gaseous and/or liquid organosilane species, will depend on the nature of the solid organosilane source, and these reactions can also be promoted by the temperature selected for the pyrolysis step. Control of the above parameters can also be used to achieve partial or complete volatilisation of the solid organosilane source instead of pyrolysis (i.e. instead of decomposition/rearrangement of the organosilane source).

For embodiments where the solid organosilane source is a polysilane, the gaseous precursor species can be obtained through a process as described in U.S. provisional application Ser. No. 60/990,447 filed on Nov. 27, 2007, the disclosure of which is incorporated herein by reference in its entirety.

The heating of the solid organosilane source in the heating chamber may be performed by electrical heating, UV irradiation, IR irradiation, microwave irradiation, X-ray irradiation, electronic beams, laser beams, induction heating, or the like.

The heating chamber is heated to a temperature in the range of, for example, from about 50 to about 700° C., from about 100 to about 700° C., from about 150 to about 700° C., from about 200 to about 700° C., from about 250 to about 700° C., from about 300 to about 700° C., from about 350 to about 700° C., from about 400 to about 700° C., from about 450 to about 700° C., from about 500 to about 700° C., from about 550 to about 700° C., about 600 to about 700° C., from about 650 to about 700° C., from about 50 to about 650° C., from about 50 to about 600° C., from about 50 to about 550° C., from about 50 to about 500° C., from about 50 to about 450° C., from about 50 to about 400° C., from about 50 to about 350° C., from about 50 to about 300° C., from about 50 to about 250° C., from about 50 to about 200° C., from about 50 to about 150° C., from about 50 to about 100° C., from about 100 to about 650° C., from about 150 to about 600° C., from about 200 to about 550° C., from about 250 to about 500° C., from about 300 to about 450° C., from about 350 to about 400° C., from about 475 to about 500° C., about 50° C., about 100° C., about 150° C., about 200° C., about 250° C., about 300° C., about 350° C., about 400° C., about 450° C., about 500° C., about 550° C., about 600° C., about 650° C., or about 700° C. A higher temperature can increase the rate at which the gaseous precursor compounds are produced from the solid organosilane source.

In one embodiment, the heating chamber is heated at a rate of up to 150° C. per hour until the desired temperature is reached, at which temperature the chamber is maintained. In another embodiment, a rate of temperature increase of up to about 20° C. per minute can be used. The temperature can also be increased to a first value at which pyrolysis proceeds, and then changed on one or more occasion, e.g. in order to vary the rate at which the mixture of gaseous precursor compound is produced or to vary the pressure within the chamber.

In one embodiment the temperature and pressure within the heating chamber are controlled, and production of the gaseous precursor can be driven by reducing the pressure, by heating the organosilane source, or by a combination thereof. Selection of specific temperature and pressure values for the heating chamber can also be used to control the nature of the gaseous precursor obtained.

In the embodiment where the solid organosilane source is a polysilane, one possible pyrolisis reaction leads to the formation of Si—Si crosslinks within the solid polysilane, which reaction usually takes place up to about 375° C. Another possible reaction is referred to as the Kumada rearrangement, which typically occurs at temperatures between about 225° C. to about 350° C., wherein the Si—Si backbone chain becomes a Si—C—Si backbone chain. While this type of reaction is usually used to produce a non-volatile product, the Kumada re-arrangement can produce volatile polycarbosilane oligomers, silanes and/or methyl silanes. While the amount of gaseous species produced by way of the Kumada rearrangement competes with the production of non-volatile solid or liquid polycarbosilane, the production of such species, while detrimental to the overall yield, can prove a useful aspect of the gas evolution process in that any material, liquid or solid, that is left in the heating chamber is in some embodiments turned into a harmless and safe ceramic material, leading to safer handling of the material once the process is terminated.

For the embodiment where the solid organosilane is a polysilane, the pressure within the heating chamber can be maintained at a predetermined pressure or within a predetermined pressure range in order to provide a desired molar ratio of gaseous precursor compounds in the produced gaseous mixture. Generally, maintaining a high pressure, e.g. 600 to 900 psi, favours the production of gaseous precursor species having a lower molecular weight (e.g. a lower number of silicon atoms), while maintaining a lower pressure, e.g. 100 to 250 psi, favours the production of gaseous organosilicon species having a higher molecular weight (e.g. higher number of silicon atoms).

Gaseous Precursor Species

Generally, the gaseous precursor comprises a mixture of volatile fragments of the solid organosilane source. In the embodiment where the solid organosilane precursor is a polysilane, the gaseous precursor species is a mixture of gaseous organosilicon compounds, i.e. compounds comprising silicon, carbon and hydrogen atoms that are in the gas phase at 20° C. and 20 psi.

In one embodiment, the mixture of gaseous organosilicon compounds comprises one of more gases selected from a gaseous silane, a gaseous polysilane, or a gaseous polycarbosilane. In another embodiment, substantially all of the gaseous organosilicon compounds produced within the mixture comprise from 1 to 4 silicon atoms. By gaseous silane is meant a compound comprising a single silicon atom, by gaseous polysilane is meant a compound comprising two or more silicon atoms wherein the silicon atoms are covalently linked (e.g. Si—Si), and by gaseous polycarbosilane is meant a compound comprising two or more silicon atoms wherein at least two of the silicon atoms are linked through a non-silicon atom (e.g. Si—CH₂—Si).

In a further embodiment, the gaseous organosilicon compound can be a gaseous polycarbosilane of formula:

Si(CH₃)ₙ(H)ₘ—[(CH₂)—Si(CH₃)ₚ(H)_{q}]ₓ—Si(CH₃)_{n′}(H)_{m′}

wherein n, m, n′ and m′ independently represent an integer from 0 to 3, with the proviso that n+m=3 and n′+m′=3; p and q independently represent an integer from 0 to 2, with the proviso that p+q=2 for each silicon atom; and x is an integer from 0 to 3.

Examples of gaseous silanes and gaseous polycarbosilanes include silane, dimethyl, trimethyl silane, tetramethyl silane, [Si(CH₃)(H)₂]—CH₂—[Si(CH₃)₂(H)], [Si(CH₃)₂(H)]—CH₂—[Si(CH₃)₂(H)], [Si(CH₃)₃]—CH₂—[Si(CH₃)₂(H)], [Si(CH₃)₂(H)]—CH₂—[Si(CH₃)₂]—CH₂—[Si(CH₃)₃], [Si(CH₃)(H)₂]—CH₂—[Si(CH₃)₂]—CH₂—[Si(CH₃)(H)₂], [Si(CH₃)(H)₂]—CH₂—[Si(CH₃)₂]—CH₂—[Si(CH₃)₂(H)], [Si(CH₃)₂(H)]—CH₂—[Si(CH₃)₂]—CH₂—[Si(CH₃)₂(H)], [Si(CH₃)₂(H)]—CH₂—[Si(CH₃)₂]—CH₂—[Si(CH₃)₂]—CH₂—[Si(CH₃)₂(H)], [Si(CH₃)(H)₂]—CH₂—[Si(CH₃)₂]—CH₂—[Si(CH₃)₂]—CH₂—[Si(CH₃)₂(H)], [Si(CH₃)(H)₂]—CH₂—[Si(CH₃)₂]—CH₂—[Si(CH₃)₂]—CH₂—[Si(CH₃)(H)₂], and [Si(H)₃]—CH₂—[Si(CH₃)₂]—CH₂—[Si(CH₃)₂]—CH₂—[Si(CH₃)(H)₂].

In one embodiment, the gaseous species is a mixture comprising up to 80 wt. % methylsilane, up to 85 wt. % dimethylsilane, from 5 to 45 wt. % trimethylsilane, up to 10 wt. % tetramethylsilane, up to 35 wt. % 1,1,2-trimethylcarbodisilane, up to 20 wt. % 1,1,2,2,-tetramethycarbodisilane, and up to 10 wt. % 1,1,1,2,2-pentamethylcarbodisilane.

In another embodiment, the gaseous species is a mixture comprising up to 10 wt. % methylsilane, up to 15 wt. % dimethylsilane, from 5 to 45 wt. % trimethylsilane, up to 10 wt. % tetramethylsilane, from 10 to 35 wt. % 1,1,2-trimethylcarbodisilane, from 2 to 20 wt. % 1,1,2,2,-tetramethycarbodisilane, and up to 10 wt. % 1,1,1,2,2-pentamethylcarbodisilane.

In a further embodiment, the gaseous species is a mixture comprising from 20 to 45 wt. % methylsilane, from 35 to 65 wt. % dimethylsilane, from 5 to 15 wt. % trimethylsilane, and optionally up to 10 wt. % gaseous carbosilane species. After forming the gaseous precursor, it may be used immediately or stored under appropriate temperature and pressure conditions for later use. The process may be interrupted at this stage since the heating chamber may be external to the reactor.

Addition of a Reactant Gas

After heating, the gaseous precursor formed may be mixed with a reactant gas in the heating chamber, the deposition chamber or in a gas mixing unit. In one embodiment, the reactant gas may be in the form of a gas that is commercially available, and the gas is provided directly to the system. In another embodiment, the reactant gas is produced by heating a solid or liquid source comprising any number of elements, such as N, O, F, or a combination thereof.

In one example, the reactant gas may be a nitrogen based gas such as NH₃, N₂, or NCl₃, an oxygen based gas such as CO, O₂, O₃, CO₂ or a combination thereof.

In an embodiment, the reactant gas may also comprise F, Al, B, Ge, Ga, P, As, N, In, Sb, S, Se, Te, In and Sb in order to obtain a doped SiC film.

Configuration of Heating and Deposition Chambers

The process may be carried with a variety of system configurations, such as a heating chamber and a deposition chamber; a heating chamber, a gas mixing unit and a deposition chamber; a heating chamber, a gas mixing unit and a plurality of deposition chambers; or a plurality of heating chambers, a gas mixing unit and at least one deposition chamber. In a preferred embodiment, the deposition chamber is within a reactor and the heating chamber is external to the reactor.

For high throughput configurations, multiple units of the heating chamber may be integrated. Each heating chamber in the multiple-unit configuration may be of a relatively small scale in size, so that the mechanical construction is simple and reliable. All heating chambers may supply common gas delivery, exhaust and control systems so that cost is similar to a larger conventional reactor with the same throughput. In theory, there is no limit to the number of reactors that may be integrated into one system.

The process may also utilize a regular mass flow or pressure controller to more accurately deliver appropriate process demanded flow rates. The gaseous precursor may be transferred to the deposition chamber in a continuous flow or in a pulsed flow.

The process may in some embodiments utilize regular tubing without the need of special heating of the tubing as is the case in many liquid source CVD processes in which heating the tubing lines is essential to eliminate source vapor condensation, or earlier decomposition of the source.

Deposition Chamber

When it is desired to form a film, the substrate is placed into the deposition chamber, which is evacuated to a sufficiently low pressure, and the gaseous precursor and optionally the reactant and carrier gas are introduced continuously or pulsed. Any pressure can be selected as long as the energy source selected to effect the deposition can be used at the selected pressure. For example, when plasma is used as the energy source, any pressure under which a plasma can be formed is suitable. In embodiments of the present invention the pressure can be from about 50 to about 500 mTorr, from about 100 to about 500 mTorr, from about 150 to about 500 mTorr, from about 200 to about 500 mTorr, from about 200 to about 500 mTorr, from about 250 to about 500 mTorr, from about 300 to about 500 mTorr, from about 350 to about 500 mTorr, from about 400 to about 500 mTorr, from about 450 to about 500 mTorr, from about 50 to about 450 mTorr, from about 50 to about 400 mTorr, from about 50 to about 350 mTorr, from about 50 to about 300 mTorr, from about 50 to about 250 mTorr, from about 50 to about 200 mTorr, from about 50 to about 150 mTorr, from about 50 to about 100 mTorr, from about 100 to about 450 mTorr, from about 150 to about 400 mTorr, from about 200 to about 350 mTorr, from about 250 to about 300 mTorr, from about 50 mTorr to about 5 Torr, from about 50 mTorr to about 4 Torr, from about 50 mTorr to about 3 Torr, from about 50 mTorr to about 2 Torr, from about 50 mTorr to about 1 Torr, about 50 mTorr, about 100 mTorr, about 150 mTorr, about 200 mTorr, about 250 mTorr, about 300 mTorr, about 350 mTorr, about 400 mTorr, about 450 mTorr, about 500 mTorr, about 1 Torr, about 2 Torr, about 3 Torr, about 4 Torr, or about 5 Torr.

The substrate is held at a temperature in the range of, for example, from about 25 to about 500° C., from about 50 to about 500° C., from about 100 to about 500° C., from about 150 to about 500° C., from about 200 to about 500° C., from about 250 to about 500° C., from about 300 to about 500° C., from about 350 to about 500° C., from about 400 to about 500° C., from about 450 to about 500° C., from about 25 to about 450° C., from about 25 to about 400° C., from about 25 to about 350° C., from about 25 to about 300° C., from about 25 to about 250° C., from about 25 to about 200° C., from about 25 to about 150° C., from about 25 to about 100° C., from about 25 to about 50° C., from about 50 to about 450° C., from about 100 to about 400° C., from about 150 to about 350° C., from about 200 to about 300° C., about 25° C., about 50° C., about 100° C., about 150° C., about 200° C., about 250° C., about 300° C., about 350° C., about 400° C., about 450° C., or about 500° C.

Any system for conducting energy induced chemical vapor deposition (CVD) may be used for the method of the present invention. Other suitable equipment will be recognised by those skilled in the art. The typical equipment, gas flow requirements and other deposition settings for a variety of PECVD deposition tools used for commercial coating solar cells can be found in True Blue, Photon International, March 2006 pages 90-99 inclusive, the contents of which are enclosed herewith by reference.

The energy source in the deposition chamber may be, for example, electrical heating, hot filament processes, UV irradiation, IR irradiation; microwave irradiation, X-ray irradiation, electronic beams, laser beams, plasma, or RF. In a preferred embodiment, the energy source is plasma.

For example, suitable plasma deposition techniques may be plasma enhanced chemical vapor deposition (PECVD), radio frequency plasma enhanced chemical vapor deposition (RF-PECVD), electron-cyclotron-resonance plasma-enhanced chemical-vapor deposition (ECR-PECVD), inductively coupled plasma-enhanced chemical-vapor deposition (ICP-ECVD), plasma beam source plasma enhanced chemical vapor deposition (PBS-PECVD), or combinations thereof. Furthermore, other types of deposition techniques suitable for use in manufacturing integrated circuits or semiconductor-based devices may also be used.

For embodiments where the energy used during the deposition is plasma, e.g. for PE-CVD, the values of x and y may be controlled by suitably selecting conditions for (1) the generation of the plasma, (2) the temperature of the substrate, (3) the power and frequency of the reactor, (4) the type and amount of gaseous precursor introduced into the deposition chamber, and (5) the mixing ratio of gaseous precursor and reactant gas.

For example, the silicon:carbon ratio of the silicon carbide layer is tunable in that it may be varied as a function of the RF power. The silicon:carbon ratio may be in a range of about 1:2 to about 2:1. For example, the silicon:carbon ratio in a silicon carbide layer formed at RF power of 900 W is about 0.94:1, while silicon:carbon ratio of a silicon carbide layer formed at RF power of 400 W is 1.3:1. A stoichiometric silicon carbide layer may be formed at RF power of about 700 W.

The silicon:carbon ratio may also be varied as a function of substrate temperature. More particularly, as the substrate temperature is increased, the silicon:carbon ratio in the deposited silicon carbide layer decreases.

The silicon:carbon ratio is also tunable as a function of the composition of the gas mixture during SiC layer formation.

Other Processes

As noted above, the solid organosilane source can be heated to volatilize the solid organosilane, or to obtain a gaseous and/or liquid pyrolysis product.

In one embodiment, the solid polymeric source (e.g. PDMS or PCMS) can be formed into a liquid polycarbosilane. A solvent (e.g. hexane, THF) may optionally be used to thin the liquid to achieve desirable rheological properties, and the liquid is deposited onto a substrate by e.g. spin coating, dip coating, spraying with conventional methodologies. Similarly, electrostatic spray techniques may be used with the liquid. Once the optional solvent evaporates, leaving the PCMS/PDMS behind, the obtained coating may be fired with one or more energy sources (e.g. rapid thermal processing, RTP using high intensity lamps) into a SiC film. The firing step can optionally be carried out in the presence of hydrogen gas and/or in the presence of one or more other gases. In another embodiment, a mixture of gaseous and liquid products obtained from the pyrolysis of the solid organosilane source can be spray coated onto a substrate and then fired as above to obtain the SiC film.

In still another embodiment, the volatilized organosilane source can be coated of a substrate, the coating then being fired to form a SiC film.

Substrate

The ARC films of the present invention can be employed in any application where an antireflection coating is needed. The ARC of the present invention is particularly applicable to solar cells fabricated from silicon. Moreover, the antireflection coating of the present invention can be applied to amorphous, crystalline, or polycrystalline silicon as well as n-doped, p-doped, or intrinsic silicon.

In one embodiment, the antireflection coating is applied to the external n-doped and/or p-doped surfaces of a solar cell to minimize reflections from these surfaces and to reduce the absorption of the light in the ARC.

### EXAMPLES

The following examples are provided to illustrate the invention. It will be understood, however, that the specific details given in each example have been selected for purpose of illustration and are not to be construed as limiting the scope of the invention. Generally, the experiments were conducted under similar conditions unless noted.

### Example 1

### SiCH Film Preparation by PECVD

Using a Trion Technologies Orion III PECVD system, deposition of a film was achieved with a 20 sccm (using silane MFC settings) stream of gas produced from pyrolysis of PDMS (see Example 9(b)). PDMS was pyrolised in a separate heated vessel to produce the gas, and the gas flow was then fed to the PECVD system.

The total flow of gas was adjusted to keep a pressure of 0.900 Torr inside the deposition chamber. The RF power was 200 watts. The duration of deposition was 9 minutes and the temperature of the substrate was 400° C.

After removal from the deposition chamber, the silicon wafer was found to be coated with an amorphous silicon carbide film having a refractive index of 2.35, a k value of ˜0.004 at 630 nm, and a film thickness of 80 nm.

### Example 2

### SiCH:N Film Preparation by PECVD

Using a Trion Technologies Orion III PECVD system, deposition of a film was achieved with 1.2 sccm NH₃ gas added to a 30 sccm (using silane MFC settings) stream of gas produced from pyrolysis of PDMS (pyrolysis achieved as in Example 1). The pressure of 0.9 Torr was kept inside the deposition chamber. The RF power was 200 watts. The duration of deposition was 6 minutes and the temperature of the substrate was 400° C.

After removal from the deposition chamber, the silicon wafer was found to be coated with an amorphous silicon carbo-nitride film having a formula of Si_{0.52}C_{0.40}N_{0.07}O_{0.01} and a refractive index of 2.56 and K-value of 0.01 at 630 nm and a film thickness of 65 nm.

### Example 3

### SiCH:N Film Preparation by PECVD

The same method as in Example 2 was carried out, using instead 2.5 sccm of NH₃ gas.

After removal from the deposition chamber, the silicon wafer was found to be coated with an amorphous silicon carbo-nitride film having a formula of Si_{0.44}C_{0.39}N_{0.12}O_{0.05} and a refractive index of 2.28 and K-value of 0.006 at 630 nm and a film thickness of 77 nm.

### Example 4

### SiCH:N Film Preparation by PECVD

The same method as in Example 2 was carried out, using instead 5 sccm of NH₃ gas.

After removal from the deposition chamber, the silicon wafer was found to be coated with an amorphous silicon carbo-nitride film having a formula of Si_{0.46}C_{0.32}N_{0.20}O_{0.02} and a refractive index of 2.25 and K-value of 0.007 at 630 nm and a film thickness of 70 nm.

### Example 5

### SiCH:N Film Preparation by PECVD

The same method as in Example 2 was carried out, using instead 10 sccm of NH₃ gas.

After removal from the deposition chamber, the silicon wafer was found to be coated with an amorphous silicon carbo-nitride film having a formula of Si_{0.40}C_{0.28}N_{0.29}O_{0.03} and a refractive index of 1.97 and K-value of 0.004 at 630 nm and a film thickness of 85 nm.

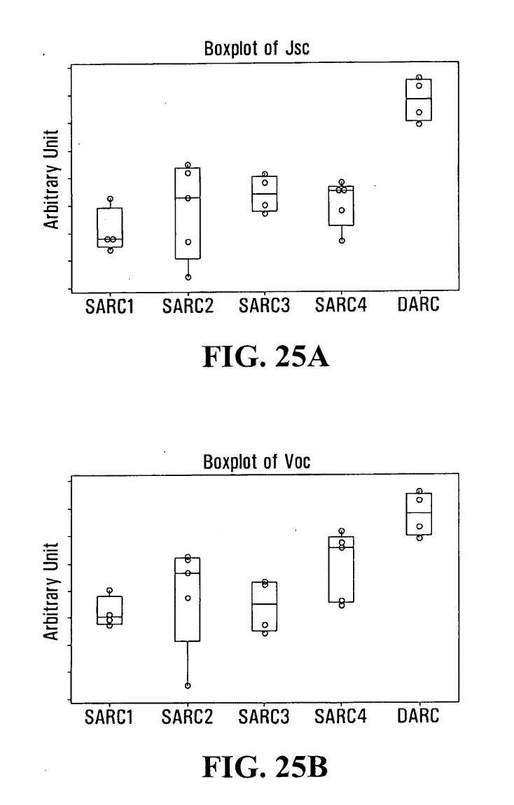

Graphical representation of the results of Examples 1 to 5 is provided in FIG. 24.

### Example 6

### Determination of Film Stress

Using a standard method for measuring stress in thin films, samples were prepared by coating a thicker film (i.e. thicker than used for ARC) on a thin Silicon wafer. The bow of the wafers was measured before coating.

The total internal stress (σₜₒₜ) was calculated by measuring the curvature of the c-Si substrate before and after deposition of SiC coating, that is then applied to the Stoney formula:

$$σ = \frac{1}{6 R} \frac{{E}_{s} {d}_{s}^{2}}{( 1 - {v}_{s} ) d}$$

$$where \text{:}$$

$$\frac{{E}_{s}}{( 1 - {v}_{s} )}$$

is the biaxial elastic modulus of the substrate [1.0805×10¹¹ Pa for the (100) silicon wafers], dₛ is the substrate thickness (m), d_{f} is the film thickness (m), Eₛ is the substrate Young's modulus (Pa), νₛ is the substrate Poisson ratio,

and

$$R = \frac{{R}_{1} {R}_{2}}{{R}_{1} - {R}_{2}}$$

where R₁ is the measured radius of curvature of the substrate (before deposition), R₂ is the measured radius of curvature of the substrate and film (after deposition).

The curvature was measured with a Tencor FLX 2900 Class IIIa laser with 4 milliwatts (mW) power and 670 nanometers (nm) wavelength. Internal stress can be measured as a function of time or temperature.

Table 2 displays the results of the radius curvature of a silicon crystal, with a thickness of 50 μm, before and after the deposition of SiC coating and Table 3 shows the results of the radius curvature of a silicon crystal, with a thickness of 350 μm, before and after the deposition of SiC coating. The R and the internal stress are calculated with the equations above and two measurements were performed on each wafer (results a and b).

TABLE 2
Internal stress measurement results for 50 μm thick silicon crystal

| | Before | After | | |
|---|---|---|---|---|
| | depositions | depositions | | Internal |
| | radius curv. (R₁) | radius curv. (R₂) | | stress |
| Wafer # | (m) | (m) | R (m) | σ₁ (Mpa) |
| 1a | −14.652 | −0.115 | −0.116 | −162 |
| 1b | −16.115 | −0.107 | −0.108 | −175 |
| 2a | −47.265 | −0.122 | −0.122 | −154 |
| 2b | −11.874 | −0.142 | −0.144 | −131 |
| 3a | −17.963 | −0.107 | −0.108 | −175 |
| 3b | −18.974 | −0.132 | −0.133 | −141 |

The average internal stress (σ is (−152 ± 18) MPa.

TABLE 3
Internal stress measurement results for 350 μm thick silicon crystal

| | Before | After | | |
|---|---|---|---|---|
| | depositions | depositions | | Internal |
| | radius curv. (R₁) | radius curv. (R₂) | | stress |
| Wafer # | (m) | (m) | R (m) | σ₁ (Mpa) |
| 2a | 25.94 | −15.03 | −9.516 | −97 |
| 2b | 28.17 | −14.48 | −9.564 | −96 |
| 3a | 19.81 | −20.38 | −10.045 | −92 |
| 3b | 29.62 | −13.38 | −9.217 | −100 |
| 4a | 56.74 | −11.12 | −9.298 | −99 |
| 4b | −267.38 | −8.3 | −8.566 | −108 |

The average internal stress (σ is (−99 ± 5) MPa.

The values of the internal stress for all the samples measured in parallel and perpendicular were found to be similar. The internal stress difference between the two thickness of the substrate is negligible. The internal stress in all samples is stable until 450° C., reaching 0 stress at ˜650° C.

### Example 7

### Effect of Annealing Temperature

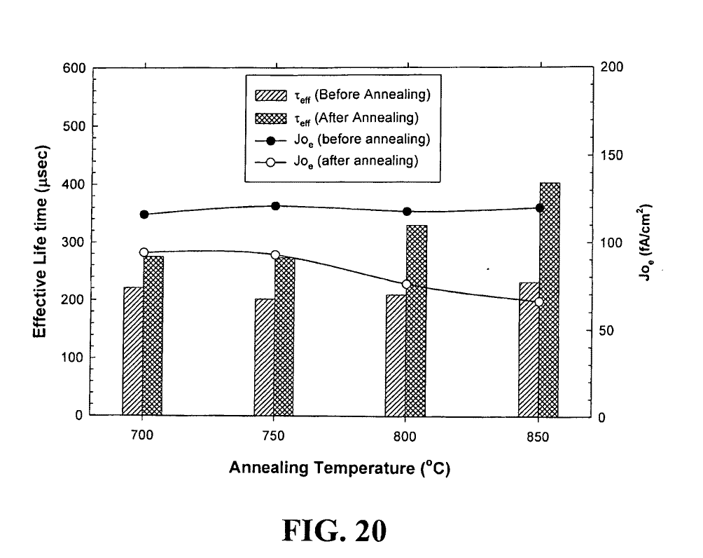

An ARC film was deposited onto a Silicon wafer FZ P-type 2 Ohm·cm by PECVD. The wafer was cut up into pieces. Each piece was measured by a Sinton WCT-120 Lifetime Tester tool to determine the carrier effective lifetime and Jₒₑ. The samples were annealed for five (5) seconds in an AG Associates 410 Rapid Thermal Anneal tool. The samples were measured again for the carrier effective lifetime and Jₒₑ. Results are shown in FIG. 20.

### Example 8

### Adhesion Measurements

Adhesion measurements were performed with a Micro Scratch Tester (CSEM, Switzerland, MST) equipment. The scratch-test method consists of generating scratches with a spherical stylus (generally Rockwell C diamond) which is drawn at a fixed rate along the sample surface, while progressively increasing the load, L. The critical load, L_{C}, is defined as the smallest load at which a recognizable failure occurs. We can distinguish different L_{C}, such as: first crack appearance (L_{C1}), first partial delamination (L_{C2}), and total delamination (L_{C3}). The L_{C} values can be determined by:

Test Conditions and Procedure

The experimental conditions are presented in Tables 4 and 5.

TABLE 4
Setting parameters for the MST with standard 200 μm tip.

| | |
|---|---|
| Load [N] | 0-30 |
| Type of the sylus | Rockwell |
| Radius of the stylus [μm] | 200 |
| Length of the scratch [mm] | 10 |
| Scratching speed [mm/min] | 10 |
| Loading rate [N/min] | 20 |

TABLE 5
Setting parameters for the MST with 100 μm tip.

| | |
|---|---|
| Load [N] | 0-20 |
| Type of the sylus | Rockwell |
| Radius of the stylus [μm] | 100 |
| Length of the scratch [mm] | 10 |
| Scratching speed [mm/min] | 10 |
| Loading rate [N/min] | 20 |

Scratches at progressive load are made on the sample of approximately 4 micron thickness using the test conditions mentioned above. Four scratches were performed, and average for L_{C1}, L_{C2} and L_{C3} values were calculated.

Results

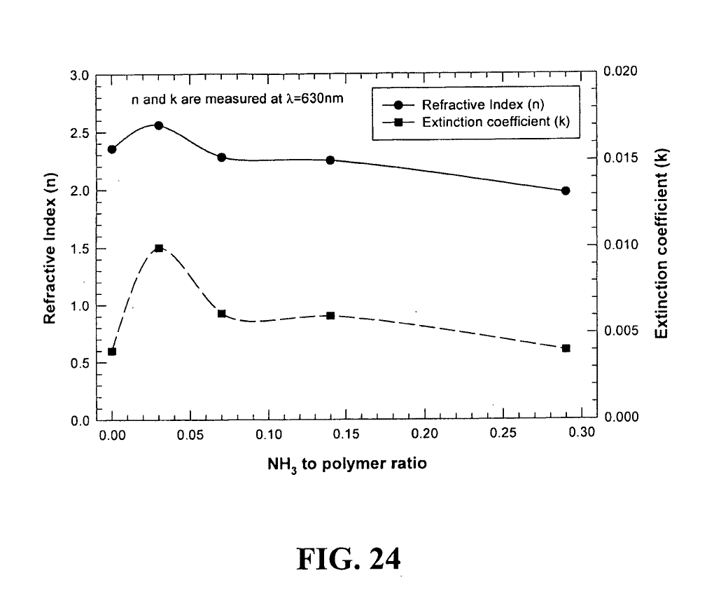

Using a standard 200 μm tip radius no delamination or cracks were observed. To increase Hertzian pressure and evaluate the adhesion, 100 μm tip radius was necessary. Table 6 summarizes the values of the mean critical loads observed for the SiC coatings using 100 μm tip radius. A micrograph of scratch no. 4 is presented in FIG. 23.

TABLE 6
Summary of the L_{C} values

| Scratch No. | L_{C1} (N) | L_{C2} (N) | L_{C3} (N) |
|---|---|---|---|
| 1 | 14.31 | 17.06 | 17.54 |
| 2 | 13.70 | 17.69 | 17.69 |
| 3 | 13.94 | 19.57 | 19.57 |
| 4 | 13.24 | 17.62 | 17.87 |
| Mean critical loads | 13.8 | 18.0 | 18.2 |
| Standard deviation: | 0.4 | 1.1 | 0.9 |

The SiC coating shows an excellent adhesion to the c-Si substrate; as a result, using a standard 200 μm radius stylus, no cracks appeared for a load reaching 30 N. However, using a 100 μm tip radius, cracking of the coating became visible at L_{C1}˜(13.8±0.4) N, partial delamination was observed at L_{C2}˜(18.0±1.1) N and total delamination was observed at L_{C3}=(18.2±0.9) N. For all scratches the OM, AE and Fₜ data provide reliable L_{C1}, L_{C2} and L_{C3} values.

### Example 9

### PDMS Pyrolysis

(a) 400 grams of polydimethylsilane (PDMS) were placed in a 2 liter stainless steel vessel provided with a heating unit and a pressure sensor. Once sealed, the gas within the vessel was purged and replaced with argon. The vessel was then heated at a rate of about 150° C. per hour to 422° C. and then maintained at this temperature for three hours. While maintaining the temperature substantially constant, gaseous products obtained were released from the vessel at 805 psi, thus reducing the pressure. Between releases of the gaseous products, the pressure within the vessel was allowed to increase as additional gaseous products were produced from the polydimethylsilane. The pressure in the vessel was maintained between 600° C. and 900 psi.

Table 7 provides the results from GC-MS analysis of the gas mixture produced from the process described in Example 9(a). The table also provides potential identification of the gaseous organosilicon compounds contained in the produced mixture, deduced from the GC-MS results.

TABLE 7

| | | | Elution | | |
|---|---|---|---|---|---|
| | Group | | time | Possible structure/ | Molecular Weight |
| Group | % | Peak % | (min) | compound | from Possible Structure |
| 0-Si | 0.17 | 0.17 | 3.563 | Unknown | |
| 1-Si | 67.27 | 44.50 | 9.247 | 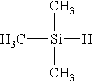 | Molecular Weight = 74.20 Exact mass = 74 Molecular Formula = C3H10Si Molecular Composition = C 48.56% H 13.58% Si 37.85% |
| | | 8.30 | 9.387 | 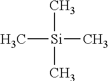 | Molecular Weight = 88.23 Exact mass = 88 Molecular Formula = C4H12Si Molecular Composition = C 54.46% H 13.71% Si 31.83% |
| | | 14.47 | Others | Dimethylsilane | |
| 2-Si | 32.59 | 6.30 | 11.422 | 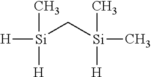 | Molecular Weight = 118.33 Exact mass = 118 Molecular Formula = C4H14Si2 Molecular Composition = C 40.60% H 11.93% Si 47.47% |
| | | 18.87 | 13.11 | 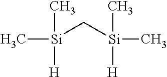 | Molecular Weight = 132.36 Exact mass = 132 Molecular Formula = C5H16Si2 Molecular Composition = C 45.37% H 12.19% Si 42.44% |
| | | 4.80 | 15.221 | 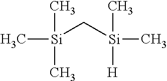 | Molecular Weight = 146.38 Exact mass = 146 Molecular Formula = C6H16Si2 Molecular Composition = C 49.23% H 12.39% Si 38.37% |
| | | 2.62 | Others | Unknown | |
| 3-Si | 0.16 | 0.0 | 27.162 | | |
| | | 0.16 | 27.995 | 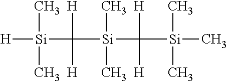 | Molecular Weight = 218.57 Exact mass = 218 Molecular Formula = C9H26Si3 Molecular Composition = C 49.46% H 11.99% Si 38.55% |
| | | 0.0 | 28.795 | 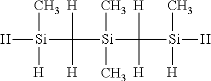 | Molecular Weight = 190.51 Exact mass = 190 Molecular Formula = C7H22Si3 Molecular Composition = C 44.13% H 11.64% Si 44.23% |
| | | 0.0 | 28.927 | 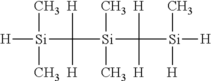 | Molecular Weight = 176.48 Exact mass = 176 Molecular Formula = C9H20Si3 Molecular Composition = C 40.83% H 11.42% Si 47.74% |
| | | 0.0 | 29.732 | 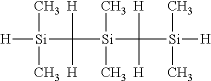 | Molecular Weight = 204.54 Exact mass = 204 Molecular Formula = C8H24Si3 Molecular Composition = C 46.98% H 11.83% Si 41.19% |
| 4-Si | 0.0 | 0.0 | 30.519 | 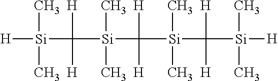 | Molecular Weight = 276.72 Exact mass = 276 Molecular Formula = C11H32Si4 Molecular Composition = C 47.75% H 11.66% Si 40.60% |
| | | 0.0 | 30.9 | | |
| | | 0.0 | 34.745 | 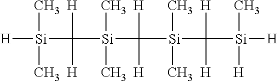 | Molecular Weight = 262.69 Exact mass = 262 Molecular Formula = C10H30Si4 Molecular Composition = C 45.72% H 11.51% Si 42.77% |
| | | 0.0 | 35.103 | 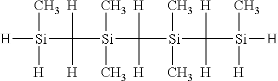 | Molecular Weight = 248.67 Exact mass = 248 Molecular Formula = C9H28Si4 Molecular Composition = C 43.47% H 11.35% Si 45.18% |
| | | 0.0 | 35.656 | 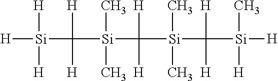 | Molecular Weight = 234.64 Exact mass = 234 Molecular Formula = C8H26Si4 Molecular Composition = C 40.95% H 11.17% Si 47.88% |

(b) The process described in Example 9 (a) was repeated, with the exception that the pressure within the vessel was maintained between about 100 and about 200 psi.

Table 8 provides the results from GC-MS analysis of the gas mixture produced from the process described in Example 9(b). The table also provides potential identification of the gaseous organosilicon compounds contained in the produced mixture, deduced from the GC-MS results.

TABLE 8

| | | | Elution | | |
|---|---|---|---|---|---|
| | Group | | time | Possible structure/ | Molecular Weight |
| | % | Peak % | (min) | compound | from Possible Structure |
| 1-Si | 13.7 | 6.2 | 9.247 | 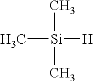 | Molecular Weight = 74.20 Exact Mass = 74 Molecular Formula = C3H10Si Molecular Composition = C 48.56% H 13.58% Si 37.85% |
| | | 7.5 | 9.387 | 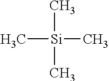 | Molecular Weight = 88.23 Exact mass = 88 Molecular Formula = C4H12Si Molecular Composition = C 54.46% H 13.71% Si 31.83% |
| 2-Si | 12.5 | 1.0 | 11.422 | 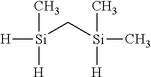 | Molecular Weight = 118.33 Exact mass = 118 Molecular Formula = C4H14Si2 Molecular Composition = C 40.60% H 11.93% Si 47.47% |
| | | 2.1 | 13.11 | 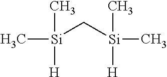 | Molecular Weight = 132.36 Exact mass = 132 Molecular Formula = C5H16Si2 Molecular Composition = C 45.37% H 12.19% Si 42.44% |
| | | 8.8 | 15.221 | 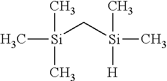 | Molecular Weight = 146.38 Exact mass = 146 Molecular Formula = C6H16Si2 Molecular Composition = C 49.23% H 12.39% Si 38.37% |
| | | 0.6 | 24.745 | Unknown | |
| 3-Si | 63.2 | 2.3 | 27.162 | Unknown | |
| | | 6.8 | 27.995 | 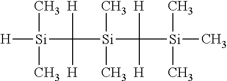 | Molecular Weight = 218.57 Exact mass = 218 Molecular Formula = C9H16Si3 Molecular Composition = C 49.46% H 11.99% Si 38.55% |
| | | 5.7 | 28.795 | 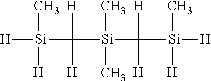 | Molecular Weight = 190.51 Exact mass = 190 Molecular Formula = C7H22Si3 Molecular Composition = C 44.13% H 11.64% Si 44.23% |
| | | 14.4 | 28.927 | 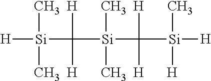 | Molecular Weight = 176.48 Exact mass = 176 Molecular Formula = C9H20Si3 Molecular Composition = C 40.83% H 11.42% Si 47.74% |
| | | 34.0 | 29.732 | 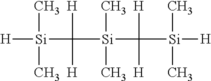 | Molecular Weight = 204.54 Exact mass = 204 Molecular Formula = C8H24Si3 Molecular Composition = C 46.98% H 11.83% Si 41.19% |
| 4-Si | 10.6 | 1.4 | 30.519 | 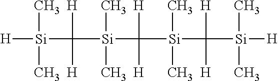 | Molecular Weight = 276.72 Exact mass = 276 Molecular Formula = C11H32Si4 Molecular Composition = C 47.75% H 11.66% Si 40.60% |
| | | 0.97 | 30.9 | Unknown | |
| | | 3.2 | 34.745 | 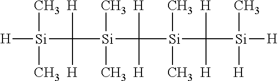 | Molecular Weight = 262.69 Exact mass = 262 Molecular Formula = C10H30Si4 Molecular Composition = C 45.72% H 11.51% Si 42.77% |
| | | 1.8 | 35.103 | 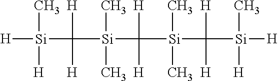 | Molecular Weight = 248.67 Exact mass = 248 Molecular Formula = C9H28Si4 Molecular Composition = C 43.47% H 11.35% Si 45.18% |
| | | 3.3 | 35.656 | 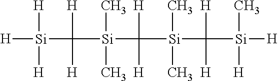 | Molecular Weight = 234.64 Exact mass = 234 Molecular Formula = C8H26Si4 Molecular Composition = C 40.95% H 11.17% Si 47.88% |

c) 50 grams of polydimethylsilane (PDMS) were placed in a 5 litre stainless steel vessel provided with a heating unit and a pressure sensor. Once sealed, the gas within the vessel was purged and replaced with argon. The vessel was then heated at a rate of about 20° C. per hour to about 500° C. Several gas samples were analyzed by Gas Chromatography (GC) during the pyrolysis step, the results of which are shown in Table 9. The table provides the analysis for the gas taken at different pressures during the process. MS, DMS and TMS represent methyl silane, dimethyl silane and trimethyl silane, respectively. Carbosilane represents one or more gaseous carbosilane species.

TABLE 9
Gas composition prior to deposition

| Pressure | MS | DMS | TMS | Carbosilane | Others |
|---|---|---|---|---|---|
| (psi) | % | % | % | % | % |
| 120 | 21.75 | 62.24 | 12.11 | 1.58 | 2.04 |
| 110 | 25.39 | 56.12 | 16.38 | 1.32 | 0.78 |
| 105 | 31.22 | 49.61 | 16.71 | 1.74 | 0.71 |
| 92.5 | 35.07 | 45.74 | 15.62 | 2.82 | 0.75 |
| 82.5 | 35.58 | 45.64 | 15.22 | 2.81 | 0.75 |
| 65 | 36.93 | 44.47 | 13.78 | 3.80 | 1.02 |
| 57 | 39.69 | 41.96 | 13.71 | 3.44 | 1.19 |
| 39 | 41.16 | 39.78 | 12.49 | 4.79 | 1.76 |
| 13 | 41.35 | 38.02 | 9.89 | 5.09 | 5.64 |

### Example 10

### Solar Cell with Double Layer Antireflective Coating

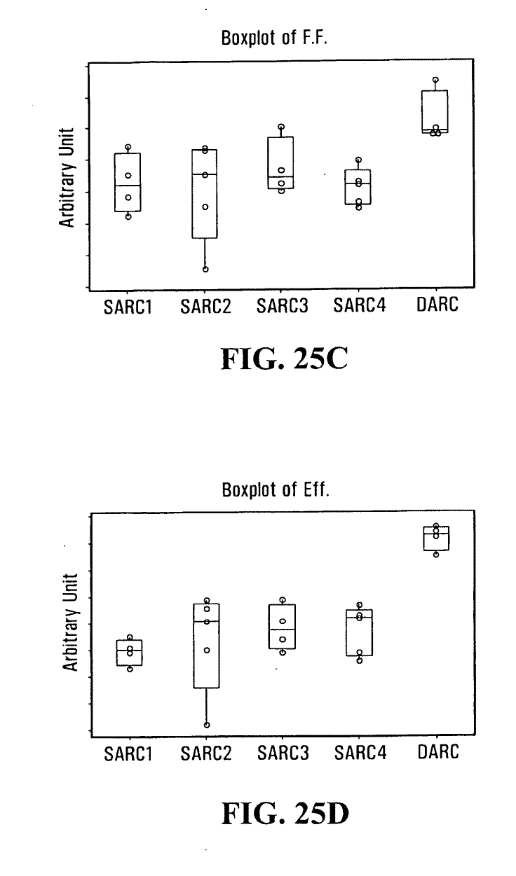

The same method as in Example 1 or 2 was carried out, to prepare solar cells with a SiCN antireflective coating (SARC 1-4) or a double layer antireflective coating comprising a SiC layer and a SiCN layer (DARC). The deposition conditions for each embodiment are provided in Table 10. The optical properties of the films are provided in Table 11. The solar cell parameters, Jsc, short circuit current, Voc, open circuit voltage, F.F., fill factor and Eff., conversion efficiency for each cell are provided in FIGS. 25a)-d).

TABLE 10
Deposition conditions of antireflective coatings

| | Plasma | Temper- | | Polymer | |
|---|---|---|---|---|---|
| | power | ature | Pressure | gas | NH3 gas |
| Coatings | (W) | (C.) | (mbarr) | (sccm) | (sccm) |
| SARC1 | 300 | 520 | 0.2 | 28 | 143 |
| SARC2 | 300 | 520 | 0.2 | 28 | 123 |
| SARC3 | 300 | 520 | 0.2 | 28 | 103 |
| SARC4 | 300 | 520 | 0.2 | 28 | 83 |
| DARC | 300 | 520 | 0.48 (SiC)/ | 30 (SiC)/ | 0 (SiC)/ |
| | | | 0.2 (SiCN) | 28 (SiCN) | 143 (SiCN) |

TABLE 11
Optical properties of antireflective coatings

| | | Refractive | Extinction | |
|---|---|---|---|---|
| | | index @ | coefficient | Thickness |
| coatings | Material | 630 nm | @ 630 nm | (nm) |
| SARC1 | SiCN | 1.98 | 0.0 | 80 |
| SARC2 | SiCN | 2.00 | 0.0 | 80 |
| SARC3 | SiCN | 2.02 | 0.0 | 80 |
| SARC4 | SiCN | 2.04 | 0.0 | 80 |
| DARC | SiC/SiCN | 2.60/1.98 | 0.008/0.0 | 15/65 |

All publications, patents and patent applications cited in this specification are herein incorporated by reference as if each individual publication, patent or patent application were specifically and individually indicated to be incorporated by reference. The citation of any publication is for its disclosure prior to the filing date and should not be construed as an admission that the present invention is not entitled to antedate such publication by virtue of prior invention. Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

It must be noted that as used in this specification and the appended claims, the singular forms “a”, “an”, and “the” include plural reference unless the context clearly dictates otherwise. Unless defined otherwise all technical and scientific terms used herein have the same meaning as commonly understood to one of ordinary skill in the art to which this invention belongs.

1. An antireflective coating comprising an amorphous silicon carbide-based film, which film further comprises hydrogen atoms and optionally further comprises oxygen and/or nitrogen atoms, the film having an effective refractive index (n) between about 2.3 and about 2.7 and an extinction coefficient (k) of less than about 0.01 at a wavelength of 630 nm.

2. The antireflective coating according to claim 1, wherein the amorphous silicon carbide-based film is an amorphous silicon carbide, amorphous silicon carbonitride, amorphous silicon oxycarbonitride or amorphous silicon oxycarbide film.

3. (canceled)

4. The antireflective coating according to claim 1, wherein the film has a plurality of layers and the refractive index of each layer varies from about 1.5 to about 2.7.

5. The antireflective coating according to claim 1, wherein the film has a graded refractive index along a thickness.

6. The antireflective coating according to claim 1, wherein the extinction coefficient (k) is less than 0.001.

7. The antireflective coating according to claim 1, which does not absorb more than 1% of incident light in the wavelength range of 300-1200 nm.

8. (canceled)

9. The antireflective coating according to claim 1, wherein the film, deposited on a silicon substrate and covered by glass, has an average light reflectivity at wavelengths from 400-1200 nm of 7% or less.

10-15. (canceled)

16. The antireflective coating according to claim 1, wherein the film has a hydrogen concentration, in atomic percent, from about 10 to about 40%, preferably from about 10% to about 35%, more preferably from about 10 to about 30%, or most preferably from about 10 to about 15%.

17. The antireflective coating according to claim 1, wherein the film has a Si concentration, in atomic percent, from about 30 to about 70%, preferably from greater than 35% to about 60%, more preferably from about 40 to about 60%, still more preferably from about 45 to about 55% or most preferably about 50%.

18. The antireflective coating according to claim 1, wherein the film has a carbon concentration, in atomic percent, from about 3 to about 60%, preferably from about 10 to about 50%, more preferably from about 20 to about 40%, or most preferably from about 25 to about 35%.

19. The antireflective coating according to claim 1, wherein the film has a nitrogen concentration, in atomic percent, from about 0 to about 50%, for example from about 10 to about 45%, from about 20 to about 40%, or from about 25 to about 35%.

20-38. (canceled)

39. An antireflective coating comprising two or more layers, wherein at least one layer is as defined in claim 1.

40. A solar cell comprising an antireflective coating as defined in claim 39.

41. The solar cell according to claim 40, which comprises a glass cover.

42-44. (canceled)

45. The antireflective coating according to claim 1, which is prepared by chemical vapour deposition of silane, methylsilane, dimethylsilane, trimethylsilane, tetramethylsilane, or a combination thereof.

46. The antireflective coating according to claim 45, wherein the chemical vapour deposition is plasma-enhanced chemical vapour deposition.

47. The antireflective coating according to claim 45, wherein the deposition is carried out at a pressure greater than 100 Torr.

48. The antireflective coating according to claim 39, wherein the at least one layer as defined in claim 1 is an amorphous silicon carbide or an amorphous silicon carbonitride layer.

49. The antireflective coating according to claim 39, wherein the at least one layer as defined in claim 1 has a thickness of 15 nm or more.

50. The antireflective coating according to claim 39, which further comprises a siliconcarbide layer, a siliconcarbonitride layer, or a siliconoxycarbide layer.

51. The antireflective coating according to claim 39, wherein the at least one layer as defined in claim 1 is a silicon carbide layer, and the antireflective coating also comprises a silicon carbonitride layer.

52. A solar cell comprising an antireflective coating as defined in claim 1.

53. The solar cell according to claim 40, wherein in the antireflective coating, the at east one layer as defined in claim 1 is a silicon carbide layer, and the antireflective coating also comprises a silicon carbonitride layer.
